(19) United States
(12) Patent Application Publication
(10) Pub. No.: US 2026/0107823 A1
(43) Pub. Date: Apr. 16, 2026

(54) PACKAGE COMPRISING INTEGRATED DEVICES AND METALLIZATION PORTIONS

(71) Applicant: QUALCOMM Incorporated, San Diego, CA (US)

(72) Inventors: William STONE, San Diego, CA (US); Sun Woong YUN, San Diego, CA (US); Li-Sheng WENG, San Diego, CA (US)

(21) Appl. No.: 18/917,896

(22) Filed: Oct. 16, 2024

(51) Int. Cl. H01L 23/31; H01L 23/00; H01L 23/538; H01L 25/16

(52) U.S. Cl. CPC H10W 74/121; H10W 70/611; H10W 90/00; H10W 90/401; H10D 1/68; H10W 90/724

(57) ABSTRACT

A package comprising a first metallization portion; a first integrated device coupled to the first metallization portion; a second integrated device coupled to the first metallization portion; a first encapsulation layer coupled to the first metallization portion; a first passive device located in the first encapsulation layer; a first bridge located in the first encapsulation layer; a second metallization portion; a second integrated device coupled to the second metallization portion; a second integrated device coupled to the second metallization portion; a second encapsulation layer coupled to the second metallization portion; a second passive device located in the second encapsulation layer; and a second bridge located in the second encapsulation layer. The package further comprises a third metallization portion and a third encapsulation layer.

### FIELD

Various features relate to packages with integrated devices.

### BACKGROUND

A package may include a different components, such as integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with integrated devices.

One example provides a package comprising a first group and a second group. The first group comprises a first metallization portion; a first integrated device coupled to the first metallization portion; a second integrated device coupled to the first metallization portion; a first encapsulation layer coupled to the first metallization portion; a first passive device located in the first encapsulation layer; and a first bridge located in the first encapsulation layer. The second group comprises a second metallization portion; a second integrated device coupled to the second metallization portion; a second integrated device coupled to the second metallization portion; a second encapsulation layer coupled to the second metallization portion; a second passive device located in the second encapsulation layer; and a second bridge located in the second encapsulation layer. The package further comprises a third metallization portion coupled to the first group and the second group; and a third encapsulation layer at least partially encapsulating the first group and the second group.

Another example provides a method for fabricating a package. The method provides a first group comprising a first metallization portion; a first integrated device coupled to the first metallization portion; a second integrated device coupled to the first metallization portion; a first encapsulation layer coupled to the first metallization portion; a first passive device located in the first encapsulation layer; and a first bridge located in the first encapsulation layer. The method provides a second group comprising a second metallization portion; a second integrated device coupled to the second metallization portion; a second integrated device coupled to the second metallization portion; a second encapsulation layer coupled to the second metallization portion; a second passive device located in the second encapsulation layer; and a second bridge located in the second encapsulation layer. The method forms and couples a third metallization portion to the first group and the second group. The method forms a third encapsulation layer that at least partially encapsulates the first group and the second group.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes integrated devices and metallization portions.

FIG. 2 illustrates an exemplary cross sectional profile view of a package that includes integrated devices and metallization portions.

FIG. 3 illustrates an exemplary cross sectional profile view of a package that includes integrated devices and metallization portions.

FIG. 4 illustrates an exemplary cross sectional profile view of a package that includes integrated devices and metallization portions.

FIG. 5 illustrates an exemplary cross sectional profile view of a package that includes integrated devices and metallization portions.

FIG. 6 illustrates an exemplary cross sectional profile view of a package that includes integrated devices and metallization portions.

FIG. 7 illustrates an exemplary cross sectional profile view of a deep trench capacitor device.

FIG. 8A-8E illustrate an exemplary sequence for fabricating a package that includes a metallization portion and integrated devices.

FIG. 9 illustrates an exemplary flow chart of a method for fabricating a package that includes a metallization portion and integrated devices.

FIG. 10A-10B illustrate an exemplary sequence for fabricating a package that includes integrated devices and metallization portions.

FIG. 11A-11B illustrate an exemplary sequence for fabricating a package that includes integrated devices and metallization portions.

FIG. 12 illustrates an exemplary flow chart of a method for fabricating a package that includes integrated devices and metallization portions.

FIG. 13A-13B illustrate an exemplary sequence for fabricating a metallization portion.

FIG. 14 illustrates an exemplary flow chart of a method for fabricating a metallization portion.

FIG. 15 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a first group and a second group. The first group comprises a first metallization portion; a first integrated device coupled to the first metallization portion; a second integrated device coupled to the first metallization portion; a first encapsulation layer coupled to the first metallization portion; a first passive device located in the first encapsulation layer; and a first bridge located in the first encapsulation layer. The second group comprises a second metallization portion; a second integrated device coupled to the second metallization portion; a second integrated device coupled to the second metallization portion; a second encapsulation layer coupled to the second metallization portion; a second passive device located in the second encapsulation layer; and a second bridge located in the second encapsulation layer. The package further comprises a third metallization portion coupled to the first group and the second group; and a third encapsulation layer at least partially encapsulating the first group and the second group. The package provides a high performing package that includes high density interconnects, with a compact form factor.

### Exemplary Package Comprising Integrated Devices and Metallization Portions

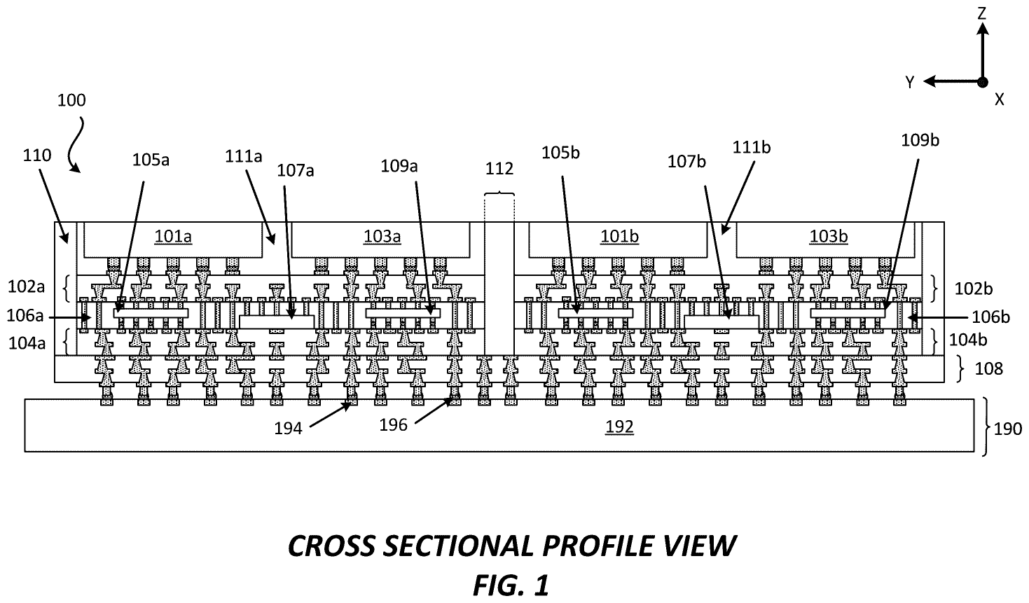

FIG. 1 illustrates a cross sectional profile view of a package 100 that includes integrated devices and metallization portions. The package 100 is coupled to a board 190 through a plurality of solder interconnects 196. The board 190 includes at least one board dielectric layer 192 and a plurality of board interconnects 194. The board 190 may include a printed circuit board (PCB). In some implementations, the package 100 may be coupled to a substrate instead of the board 190.

The package 100 includes an integrated device 101a, an integrated device 101b, an integrated device 103a, an integrated device 103b, a passive device 105a, a passive device 105b, a bridge 107a, a bridge 107b, a passive device 109a, a passive device 109b, a metallization portion 102a, a metallization portion 102b, a metallization portion 104a, a metallization portion 104b, a metallization portion 108, an encapsulation layer 106a, an encapsulation layer 106b, an encapsulation layer 110, an encapsulation layer 111a and an encapsulation layer 111b.

The package 100 includes a first sub-package comprising the integrated device 101a, the integrated device 103a, the metallization portion 102a, the metallization portion 104a, the encapsulation layer 106a, the encapsulation layer 111a, the passive device 105a, the passive device 109a and the bridge 107a. The first sub-package may be a first group of the package 100.

The package 100 also includes a second sub-package comprising the integrated device 101b, the integrated device 103b, the metallization portion 102b, the metallization portion 104b, the encapsulation layer 106b, the encapsulation layer 111b, the passive device 105b, the passive device 109b and the bridge 107b. The second sub-package may be a second group of the package 100.

The first sub-package may be coupled to the metallization portion 108. The metallization portion 104a may be coupled to the metallization portion 108. The second sub-package may be coupled to the metallization portion 108. The metallization portion 104b may be coupled to the metallization portion 108. The encapsulation layer 110 is coupled to the metallization portion 108. The encapsulation layer 110 may at least partially encapsulate the first sub-package and the second sub-package. There may be a separation 112 between the first sub-package and the second sub-package. There may be a separation 112 between the metallization portion 102a and the metallization portion 102b. There may be a separation 112 between the metallization portion 104a and the metallization portion 104b. There may be a separation 112 between the encapsulation layer 106a and the encapsulation layer 106b. The separation 112 may be a separation distance. The separation 112 may be occupied by the encapsulation layer 110.

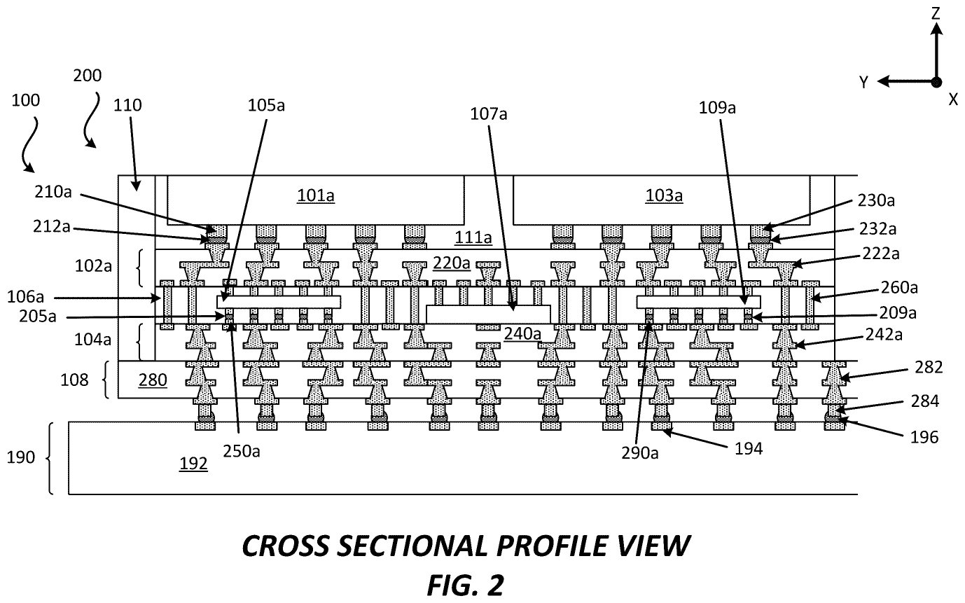

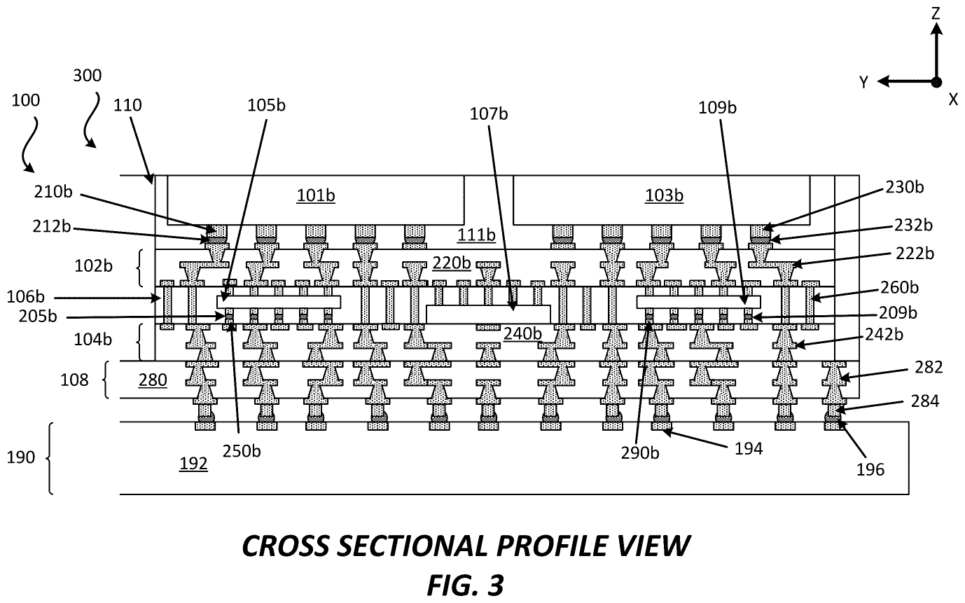

FIGS. 2 and 3 illustrate in more details the various sub-packages, components and/or configurations of the package 100. FIG. 2 illustrates a close up view of the package 100. As shown in FIG. 2, the package 100 includes a sub-package 200 (e.g., first sub-package). The sub-package 200 may be an example of a first group (e.g., first group of arrangements) of the package 100. The sub-package 200 includes the integrated device 101a, the integrated device 103a, the encapsulation layer 111a, the metallization portion 102a, the encapsulation layer 106a, the passive device 105a, the passive device 109a, the bridge 107a, the plurality of via interconnects 260a and the metallization portion 104a. The sub-package 200 may be coupled to the metallization portion 108. For example, the metallization portion 104a may be coupled to and touching the metallization portion 108. The encapsulation layer 110 may at least partially encapsulate the sub-package 200. The encapsulation layer 110 may be coupled to the metallization portion 108. The encapsulation layer 106a, the encapsulation layer 111a and/or the encapsulation layer 110 may each include a mold, a resin, an epoxy and/or a filler. In some implementations, the encapsulation layer 106a, the encapsulation layer 111a and/or the encapsulation layer 110 may include a same material. In some implementations, the encapsulation layer 106a, the encapsulation layer 111a and/or the encapsulation layer 110 may include a different material. In some implementations, the encapsulation layer 106a, the encapsulation layer 111a and/or the encapsulation layer 110 may include a same or a different composition of materials. In some implementations, the encapsulation layer 106a, the encapsulation layer 111a and/or the encapsulation layer 110 may be a continuous and/or a contiguous encapsulation layer. In some implementations, the encapsulation layer 106a, the encapsulation layer 111a and/or the encapsulation layer 110 may include at least one boundary interface between two or more encapsulation layers. In some implementations, the encapsulation layer 106a, the encapsulation layer 111a and/or the encapsulation layer 110 may be free of a boundary interface between two or more encapsulation layers.

The metallization portion 102a may include at least one dielectric layer 220a and a plurality of metallization interconnects 222a. The integrated device 101a is coupled to the plurality of metallization interconnects 222a of the metallization portion 102a through a plurality of pillar interconnects 210a and/or a plurality of solder interconnects 212a. The integrated device 103a is coupled to the plurality of metallization interconnects 222a of the metallization portion 102a through a plurality of pillar interconnects 230a and/or a plurality of solder interconnects 232a. The encapsulation layer 111a is coupled to the metallization portion 102a. The encapsulation layer 111a may at least partially encapsulate the integrated device 101a and/or the integrated device 103a.

The encapsulation layer 106a is coupled to the metallization portion 102a. The plurality of via interconnects 260a may be at least partially located in the encapsulation layer 106a. The passive device 105a, the bridge 107a and/or the passive device 109a may be at least partially located in the encapsulation layer 106a. The plurality of via interconnects 260a may be coupled to and touching the passive device 105a, the bridge 107a, the passive device 109a and the plurality of metallization interconnects 222a of the metallization portion 102a. Some of the via interconnects from the plurality of via interconnects 260a may extend through the encapsulation layer 106a.

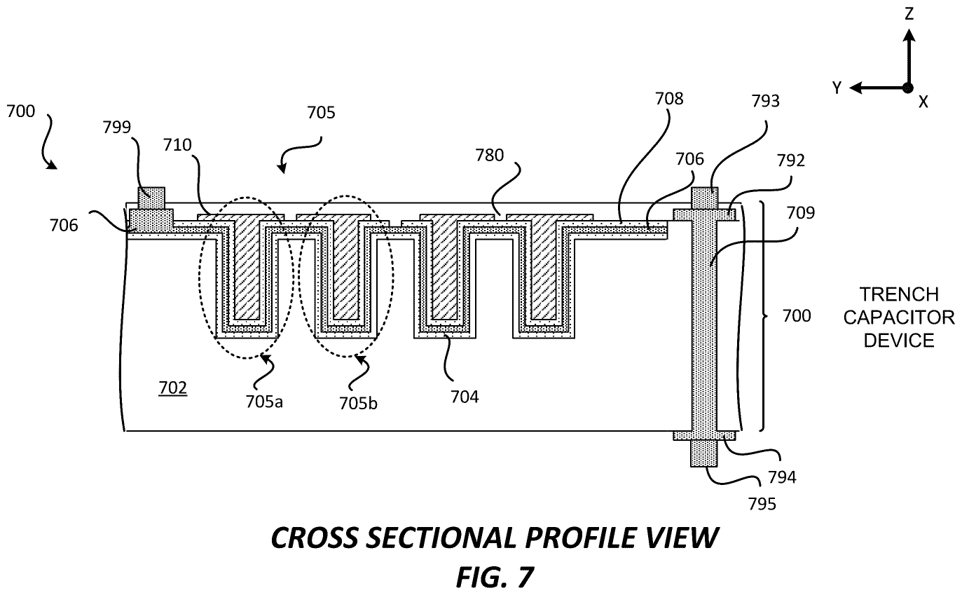

The bridge 107a may be a silicon bridge that includes a silicon base and a plurality of bridge interconnects. The plurality of bridge interconnects of the bridge 107a may be coupled to the via interconnects from the plurality of via interconnects 260a. The passive device 105a may be a deep trench capacitor device. The passive device 109a may be a deep trench capacitor device. An example of a deep trench capacitor device is further described below in at least FIG. 7. The passive device 105a may be coupled to pad interconnects 250a (e.g., pad interconnects located in the encapsulation layer 106a) through a plurality of solder interconnects 205a. The passive device 109a may be coupled to pad interconnects 290a (e.g., pad interconnects located in the encapsulation layer 106a) through a plurality of solder interconnects 209a.

The metallization portion 104a is coupled to the encapsulation layer 106a. The encapsulation layer 106a is located vertically between the metallization portion 102a and the metallization portion 104a. The metallization portion 104a may include at least one dielectric layer 240a and a plurality of metallization interconnects 242a. The plurality of metallization interconnects 242a are coupled to some of the via interconnects from the plurality of via interconnects 260a. The plurality of metallization interconnects 242a are coupled to some of the pad interconnects in the encapsulation layer 106a.

The metallization portion 104a may be coupled to the metallization portion 108. The metallization portion 108 may include at least one dielectric layer 280 and a plurality of metallization interconnects 282. The at least one dielectric layer 240a may be coupled to the at least one dielectric layer 280. There may or may not be a boundary interface between the at least one dielectric layer 240a and the at least one dielectric layer 280. The plurality of metallization interconnects 282 may be coupled to the plurality of metallization interconnects 242a. The metallization portion 104a vertically overlaps with only part of the metallization portion 108. The lateral area of the metallization portion 108 is greater than the lateral area of the metallization portion 104a. The encapsulation layer 110 is coupled to a surface of the metallization portion 108. The encapsulation layer 110 is coupled to a side surface of the metallization portion 104a, a side surface of the encapsulation layer 106a and/or a side surface of the metallization portion 102a. The plurality of metallization interconnects 242a may include a first minimum width and/or a first minimum spacing. The plurality of metallization interconnects 282 may include a second minimum width and/or a second minimum spacing. The second minimum width may be the same or different from the first minimum width. For example, the first minimum width may be less than the second minimum width. In another example, the first minimum width may be greater than the second minimum width. The second minimum spacing may be the same or different from the first minimum spacing. For example, the first minimum spacing may be less than the second minimum spacing. In another example, the first minimum spacing may be greater than the second minimum spacing.

The plurality of pillar interconnects 284 are coupled to the plurality of metallization interconnects 282. The metallization portion 108 is coupled to the plurality of board interconnects 194 through the plurality of pillar interconnects 284 and a plurality of solder interconnects 196.

In some implementations, an electrical path between the integrated device 101a and the board 190 may include (i) a pillar interconnect from the plurality of pillar interconnects 210a, (ii) a solder interconnect from the plurality of solder interconnects 212a, (iii) the plurality of metallization interconnects 222a, (iv) a via interconnect from the plurality of via interconnects 260a, (v) the plurality of metallization interconnects 242a, (vi) the plurality of metallization interconnects 282, (vii) a post interconnect from the plurality of pillar interconnects 284, and (viii) a solder interconnect from the plurality of solder interconnects 196.

In some implementations, an electrical path between the integrated device 101a and the board 190 may include (i) a pillar interconnect from the plurality of pillar interconnects 210a, (ii) a solder interconnect from the plurality of solder interconnects 212a, (iii) the plurality of metallization interconnects 222a, (iv) a via interconnect from the plurality of via interconnects 260a, (v) the passive device 105a, (vi) a solder interconnect from the plurality of solder interconnects 205a, (vii) a pad interconnect from the plurality of pad interconnects 250a, (viii) the plurality of metallization interconnects 242a, (ix) the plurality of metallization interconnects 282, (x) a pillar interconnect from the plurality of pillar interconnects 284, and (xi) a solder interconnect from the plurality of solder interconnects 196.

In some implementations, an electrical path between the integrated device 101a and the integrated device 103a may include (i) a pillar interconnect from the plurality of pillar interconnects 210a, (ii) a solder interconnect from the plurality of solder interconnects 212a, (iii) metallization interconnects from the plurality of metallization interconnects 222a, (iv) a via interconnect from the plurality of via interconnects 260a, (v) the bridge 107a, (vi) another via interconnect from the plurality of via interconnects 260a, (vii) other metallization interconnects the plurality of metallization interconnects 222a, (viii) a solder interconnect from the plurality of solder interconnects 232a, and (ix) a pillar interconnect from the plurality of pillar interconnects 230a.

FIG. 3 illustrates a close up view of the package 100. As shown in FIG. 3, the package 100 includes a sub-package 300 (e.g., second sub-package). The sub-package 300 may be an example of a second group (e.g., second group of arrangements) of the package 100. The sub-package 300 includes the integrated device 101b, the integrated device 103b, the encapsulation layer 111b, the metallization portion 102b, the encapsulation layer 106b, the passive device 105b, the passive device 109b, the bridge 107b, the plurality of via interconnects 260b and the metallization portion 104b. The sub-package 300 may be coupled to the metallization portion 108. For example, the metallization portion 104b may be coupled to and touching the metallization portion 108. The encapsulation layer 110 may at least partially encapsulate the sub-package 300. The encapsulation layer 110 may be coupled to the metallization portion 108. The encapsulation layer 106b, the encapsulation layer 111b and/or the encapsulation layer 110 may each include a mold, a resin, an epoxy and/or a filler. In some implementations, the encapsulation layer 106b, the encapsulation layer 111b and/or the encapsulation layer 110 may include a same material. In some implementations, the encapsulation layer 106b, the encapsulation layer 111b and/or the encapsulation layer 110 may include a different material. In some implementations, the encapsulation layer 106b, the encapsulation layer 111b and/or the encapsulation layer 110 may include a same or a different composition of materials. In some implementations, the encapsulation layer 106b, the encapsulation layer 111b and/or the encapsulation layer 110 may be a continuous and/or a contiguous encapsulation layer. In some implementations, the encapsulation layer 106b, the encapsulation layer 111b and/or the encapsulation layer 110 may include at least one boundary interface between two or more encapsulation layers. In some implementations, the encapsulation layer 106b, the encapsulation layer 111b and/or the encapsulation layer 110 may be free of a boundary interface between two or more encapsulation layers.

The metallization portion 102b may include at least one dielectric layer 220b and a plurality of metallization interconnects 222b. The integrated device 101b is coupled to the plurality of metallization interconnects 222b of the metallization portion 102b through a plurality of pillar interconnects 210b and/or a plurality of solder interconnects 212b. The integrated device 103b is coupled to the plurality of metallization interconnects 222b of the metallization portion 102b through a plurality of pillar interconnects 230b and/or a plurality of solder interconnects 232b. The encapsulation layer 111b is coupled to the metallization portion 102b. The encapsulation layer 111b may at least partially encapsulate the integrated device 101b and/or the integrated device 103b.

The encapsulation layer 106b is coupled to the metallization portion 102b. The plurality of via interconnects 260b may be at least partially located in the encapsulation layer 106b. The passive device 105b, the bridge 107b and/or the passive device 109b may be at least partially located in the encapsulation layer 106b. The plurality of via interconnects 260b may be coupled to and touching the passive device 105b, the bridge 107b, the passive device 109b and the plurality of metallization interconnects 222b of the metallization portion 102b. Some of the via interconnects from the plurality of via interconnects 260b may extend through the encapsulation layer 106b.

The bridge 107b may be a silicon bridge that includes a silicon base and a plurality of bridge interconnects. The plurality of bridge interconnects of the bridge 107b may be coupled to the via interconnects from the plurality of via interconnects 260b. The passive device 105b may be a deep trench capacitor device. The passive device 109b may be a deep trench capacitor device. An example of a deep trench capacitor device is further described below in at least FIG. 7. The passive device 105b may be coupled to pad interconnects 250b (e.g., pad interconnects located in the encapsulation layer 106b) through a plurality of solder interconnects 205b. The passive device 109b may be coupled to pad interconnects 290b (e.g., pad interconnects located in the encapsulation layer 106b) through a plurality of solder interconnects 209b.

The metallization portion 104b is coupled to the encapsulation layer 106b. The encapsulation layer 106b is located vertically between the metallization portion 102b and the metallization portion 104b. The metallization portion 104b may include at least one dielectric layer 240b and a plurality of metallization interconnects 242b. The plurality of metallization interconnects 242b are coupled to some of the via interconnects from the plurality of via interconnects 260b. The plurality of metallization interconnects 242b are coupled to some of the pad interconnects in the encapsulation layer 106b. The plurality of metallization interconnects 242b may include a third minimum width and/or a third minimum spacing. The plurality of metallization interconnects 282 may include a second minimum width and/or a second minimum spacing. The third minimum width of the plurality of metallization interconnects 242b may be the same or different from the first minimum width of the plurality of metallization interconnects 242a. The third minimum spacing of the plurality of metallization interconnects 242b may be the same or different from the first minimum spacing of the plurality of metallization interconnects 242a. The second minimum width may be the same or different from the third minimum width. For example, the third minimum width may be less than the second minimum width. In another example, the third minimum width may be greater than the second minimum width. The second minimum spacing may be the same or different from the third minimum spacing. For example, the third minimum spacing may be less than the second minimum spacing. In another example, the third minimum spacing may be greater than the second minimum spacing.

The metallization portion 104b may be coupled to the metallization portion 108. The metallization portion 108 may include at least one dielectric layer 280 and a plurality of metallization interconnects 282. The at least one dielectric layer 240b may be coupled to the at least one dielectric layer 280. There may or may not be a boundary interface between the at least one dielectric layer 240b and the at least one dielectric layer 280. The plurality of metallization interconnects 282 may be coupled to the plurality of metallization interconnects 242b. The metallization portion 104b vertically overlaps with only part of the metallization portion 108. The lateral area of the metallization portion 108 is greater than the lateral area of the metallization portion 104b. The encapsulation layer 110 is coupled to a surface of the metallization portion 108. The encapsulation layer 110 is coupled to a side surface of the metallization portion 104b, a side surface of the encapsulation layer 106b and/or a side surface of the metallization portion 102b.

The plurality of pillar interconnects 284 are coupled to the plurality of metallization interconnects 282. The metallization portion 108 is coupled to the plurality of board interconnects 194 through the plurality of pillar interconnects 284 and a plurality of solder interconnects 196.

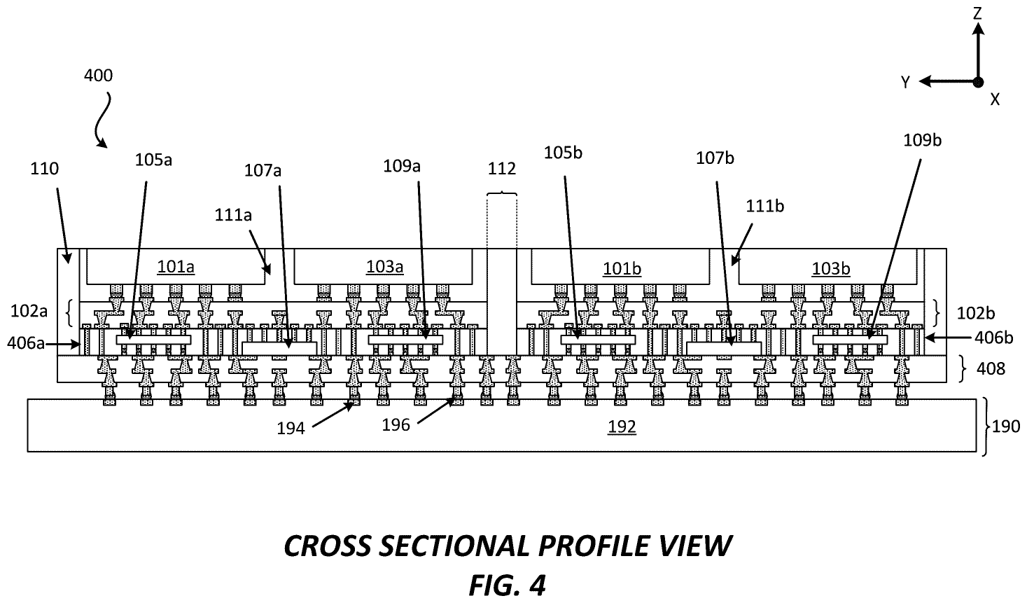

FIG. 4 illustrates a cross sectional profile view of a package 400 that includes integrated devices and metallization portions. The package 400 is coupled to a board 190 through a plurality of solder interconnects 196. The board 190 includes at least one board dielectric layer 192 and a plurality of board interconnects 194. The board 190 may include a printed circuit board (PCB). In some implementations, the package 400 may be coupled to a substrate instead of the board 190.

The package 400 includes an integrated device 101a, an integrated device 101b, an integrated device 103a, an integrated device 103b, a passive device 105a, a passive device 105b, a bridge 107a, a bridge 107b, a passive device 109a, a passive device 109b, a metallization portion 102a, a metallization portion 102b, a metallization portion 408, an encapsulation layer 406a, an encapsulation layer 406b, an encapsulation layer 110, an encapsulation layer 111a and an encapsulation layer 111b.

The package 400 includes a first sub-package comprising the integrated device 101a, the integrated device 103a, the metallization portion 102a, the encapsulation layer 406a, the encapsulation layer 111a, the passive device 105a, the passive device 109a and the bridge 107a. The first sub-package may be a first group of the package 400.

The package 400 also includes a second sub-package comprising the integrated device 101b, the integrated device 103b, the metallization portion 102b, the encapsulation layer 406b, the encapsulation layer 111b, the passive device 105b, the passive device 109b and the bridge 107b. The second sub-package may be a second group of the package 400.

The first sub-package may be coupled to the metallization portion 408. The encapsulation layer 406a may be coupled to the metallization portion 408. The second sub-package may be coupled to the metallization portion 408. The encapsulation layer 406b may be coupled to the metallization portion 408. The encapsulation layer 110 is coupled to the metallization portion 408. The encapsulation layer 110 may at least partially encapsulate the first sub-package and the second sub-package. There may be a separation 112 between the first sub-package and the second sub-package. There may be a separation 112 between the metallization portion 102a and the metallization portion 102b. There may be a separation 112 between the encapsulation layer 406a and the encapsulation layer 406a. The separation 112 may be a separation distance. The separation 112 may be occupied by the encapsulation layer 110.

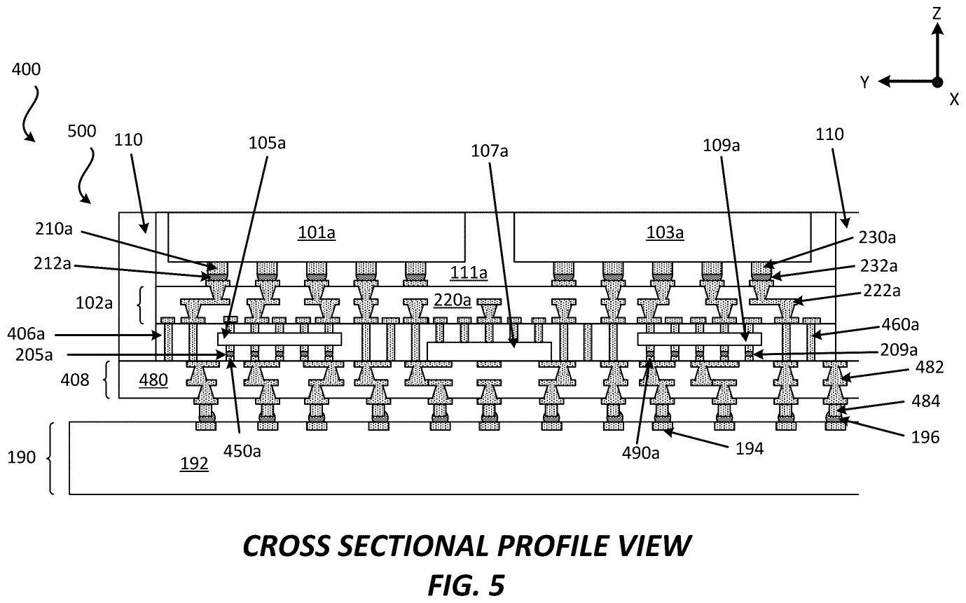

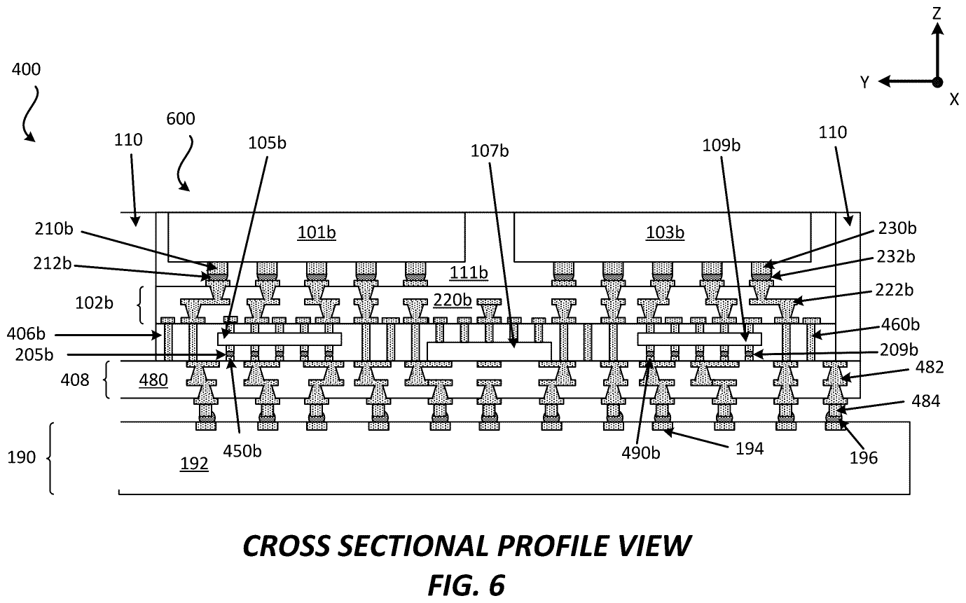

FIGS. 5 and 6 illustrate in more details the various sub-packages, components and/or configurations of the package 400. FIG. 5 illustrates a close up view of the package 400. As shown in FIG. 5, the package 400 includes a sub-package 500 (e.g., first sub-package). The sub-package 500 may be an example of a first group (e.g., first group of arrangements) of the package 400. The sub-package 500 includes the integrated device 101a, the integrated device 103a, the encapsulation layer 111a, the metallization portion 102a, the encapsulation layer 406a, the passive device 105a, the passive device 109a, the bridge 107a and the plurality of via interconnects 460a. The sub-package 500 may be coupled to the metallization portion 408. For example, the encapsulation layer 406a may be coupled to and touching the metallization portion 408. The encapsulation layer 110 may at least partially encapsulate the sub-package 500. The encapsulation layer 110 may be coupled to the metallization portion 408. The encapsulation layer 406a, the encapsulation layer 111a and/or the encapsulation layer 110 may each include a mold, a resin, an epoxy and/or a filler. In some implementations, the encapsulation layer 406a, the encapsulation layer 111a and/or the encapsulation layer 110 may include a same material. In some implementations, the encapsulation layer 406a, the encapsulation layer 111a and/or the encapsulation layer 110 may include a different material. In some implementations, the encapsulation layer 406a, the encapsulation layer 111a and/or the encapsulation layer 110 may include a same or a different composition of materials. In some implementations, the encapsulation layer 406a, the encapsulation layer 111a and/or the encapsulation layer 110 may be a continuous and/or a contiguous encapsulation layer. In some implementations, the encapsulation layer 406a, the encapsulation layer 111a and/or the encapsulation layer 110 may include at least one boundary interface between two or more encapsulation layers. In some implementations, the encapsulation layer 406a, the encapsulation layer 111a and/or the encapsulation layer 110 may be free of a boundary interface between two or more encapsulation layers. In some implementations, the presence of different materials and/or different compositions in the different encapsulation layers (e.g., 110, 111a, 111b, 406a, 406b) may result in one or more boundary interfaces between encapsulation layers.

The metallization portion 102a may include at least one dielectric layer 220a and a plurality of metallization interconnects 222a. The integrated device 101a is coupled to the plurality of metallization interconnects 222a of the metallization portion 102a through a plurality of pillar interconnects 210a and/or a plurality of solder interconnects 212a. The integrated device 103a is coupled to the plurality of metallization interconnects 222a of the metallization portion 102a through a plurality of pillar interconnects 230a and/or a plurality of solder interconnects 232a. The encapsulation layer 111a is coupled to the metallization portion 102a. The encapsulation layer 111a may at least partially encapsulate the integrated device 101a and/or the integrated device 103a.

The encapsulation layer 406a is coupled to the metallization portion 102a. The plurality of via interconnects 460a may be at least partially located in the encapsulation layer 406a. The passive device 105a, the bridge 107a and/or the passive device 109a may be at least partially located in the encapsulation layer 406a. The plurality of via interconnects 460a may be coupled to and touching the passive device 105a, the bridge 107a, the passive device 109a and the plurality of metallization interconnects 222a of the metallization portion 102a. Some of the via interconnects from the plurality of via interconnects 460a may extend through the encapsulation layer 406a.

The bridge 107a may be a silicon bridge that includes a silicon base and a plurality of bridge interconnects. The plurality of bridge interconnects of the bridge 107a may be coupled to the via interconnects from the plurality of via interconnects 460a. The passive device 105a may be a deep trench capacitor device. The passive device 109a may be a deep trench capacitor device. An example of a deep trench capacitor device is further described below in at least FIG. 7. The passive device 105a may be coupled to pad interconnects 450a (e.g., pad interconnects located in the encapsulation layer 406a) through a plurality of solder interconnects 205a. The passive device 109a may be coupled to pad interconnects 490a (e.g., pad interconnects located in the encapsulation layer 406a) through a plurality of solder interconnects 209a.

The metallization portion 408 is coupled to the encapsulation layer 406a. The encapsulation layer 406a is located vertically between the metallization portion 102a and the metallization portion 408. The metallization portion 408 may include at least one dielectric layer 480 and a plurality of metallization interconnects 482. The plurality of metallization interconnects 482 are coupled to some of the via interconnects from the plurality of via interconnects 460a. The plurality of metallization interconnects 482 are coupled to some of the pad interconnects in the encapsulation layer 406a.

The metallization portion 102a vertically overlaps with only part of the metallization portion 408. The lateral area of the metallization portion 408 is greater than the lateral area of the metallization portion 102a. The encapsulation layer 110 is coupled to a surface of the metallization portion 408. The encapsulation layer 110 is coupled to a side surface of the encapsulation layer 406a and/or a side surface of the metallization portion 102a.

The plurality of pillar interconnects 484 are coupled to the plurality of metallization interconnects 482. The metallization portion 408 is coupled to the plurality of board interconnects 194 through the plurality of pillar interconnects 484 and a plurality of solder interconnects 196.

In some implementations, an electrical path between the integrated device 101a and the board 190 may include (i) a pillar interconnect from the plurality of pillar interconnects 210a, (ii) a solder interconnect from the plurality of solder interconnects 212a, (iii) the plurality of metallization interconnects 222a, (iv) a via interconnect from the plurality of via interconnects 460a, (v) the plurality of metallization interconnects 482, (vi) a post interconnect from the plurality of pillar interconnects 484, and (vii) a solder interconnect from the plurality of solder interconnects 196.

In some implementations, an electrical path between the integrated device 101a and the board 190 may include (i) a pillar interconnect from the plurality of pillar interconnects 210a, (ii) a solder interconnect from the plurality of solder interconnects 212a, (iii) the plurality of metallization interconnects 222a, (iv) a via interconnect from the plurality of via interconnects 460a, (v) the passive device 105a, (vi) a solder interconnect from the plurality of solder interconnects 205a, (vii) a pad interconnect from the plurality of pad interconnects 250a, (viii) the plurality of metallization interconnects 482, (ix) a pillar interconnect from the plurality of pillar interconnects 484, and (x) a solder interconnect from the plurality of solder interconnects 196.

In some implementations, an electrical path between the integrated device 101a and the integrated device 103a may include (i) a pillar interconnect from the plurality of pillar interconnects 210a, (ii) a solder interconnect from the plurality of solder interconnects 212a, (iii) metallization interconnects from the plurality of metallization interconnects 222a, (iv) a via interconnect from the plurality of via interconnects 460a, (v) the bridge 107a, (vi) another via interconnect from the plurality of via interconnects 460a, (vii) other metallization interconnects the plurality of metallization interconnects 222a, (viii) a solder interconnect from the plurality of solder interconnects 232a, and (ix) a pillar interconnect from the plurality of pillar interconnects 230a.

FIG. 6 illustrates a close up view of the package 400. As shown in FIG. 5, the package 400 includes a sub-package 600 (e.g., second sub-package). The second sub-package 600 may be an example of a second group (e.g., second group of arrangements) of the package 400. The second sub-package 600 includes the integrated device 101b, the integrated device 103b, the encapsulation layer 111b, the metallization portion 102b, the encapsulation layer 406b, the passive device 105b, the passive device 109b, the bridge 107b and the plurality of via interconnects 460b. The second sub-package 600 may be coupled to the metallization portion 408. For example, the encapsulation layer 406b may be coupled to and touching the metallization portion 408. The encapsulation layer 110 may at least partially encapsulate the second sub-package 600. The encapsulation layer 110 may be coupled to the metallization portion 408. The encapsulation layer 406b, the encapsulation layer 111b and/or the encapsulation layer 110 may each include a mold, a resin, an epoxy and/or a filler. In some implementations, the encapsulation layer 406b, the encapsulation layer 111b and/or the encapsulation layer 110 may include a same material. In some implementations, the encapsulation layer 406b, the encapsulation layer 111b and/or the encapsulation layer 110 may include a different material. In some implementations, the encapsulation layer 406b, the encapsulation layer 111b and/or the encapsulation layer 110 may include a same or a different composition of materials. In some implementations, the encapsulation layer 406b, the encapsulation layer 111b and/or the encapsulation layer 110 may be a continuous and/or a contiguous encapsulation layer. In some implementations, the encapsulation layer 406b, the encapsulation layer 111b and/or the encapsulation layer 110 may include at least one boundary interface between two or more encapsulation layers. In some implementations, the encapsulation layer 406b, the encapsulation layer 111b and/or the encapsulation layer 110 may be free of a boundary interface between two or more encapsulation layers. In some implementations, the presence of different materials and/or different compositions in the different encapsulation layers (e.g., 110, 111a, 111b, 106a, 106b, 406a, 406b) may result in one or more boundary interfaces between encapsulation layers. In some implementations, when two encapsulation layers have different material composition, it may mean that one encapsulation layer may have a different percentage of a same material than the other encapsulation layer. For example, two encapsulation layers may have different material composition when one encapsulation layer may have “xy” percentage of a filler and another encapsulation layer may have “yy” percentage of the same filler, where xy is different from yy.

The metallization portion 102b may include at least one dielectric layer 220b and a plurality of metallization interconnects 222b. The integrated device 101b is coupled to the plurality of metallization interconnects 222b of the metallization portion 102b through a plurality of pillar interconnects 210b and/or a plurality of solder interconnects 212b. The integrated device 103b is coupled to the plurality of metallization interconnects 222b of the metallization portion 102b through a plurality of pillar interconnects 230b and/or a plurality of solder interconnects 232b. The encapsulation layer 111b is coupled to the metallization portion 102b. The encapsulation layer 111b may at least partially encapsulate the integrated device 101b and/or the integrated device 103b.

The encapsulation layer 406b is coupled to the metallization portion 102b. The plurality of via interconnects 460b may be at least partially located in the encapsulation layer 406b. The passive device 105b, the bridge 107b and/or the passive device 109b may be at least partially located in the encapsulation layer 406b. The plurality of via interconnects 460b may be coupled to and touching the passive device 105b, the bridge 107b, the passive device 109b and the plurality of metallization interconnects 222b of the metallization portion 102b. Some of the via interconnects from the plurality of via interconnects 460b may extend through the encapsulation layer 406b.

The bridge 107b may be a silicon bridge that includes a silicon base and a plurality of bridge interconnects. The plurality of bridge interconnects of the bridge 107b may be coupled to the via interconnects from the plurality of via interconnects 460b. The passive device 105b may be a deep trench capacitor device. The passive device 109b may be a deep trench capacitor device. An example of a deep trench capacitor device is further described below in at least FIG. 7. The passive device 105b may be coupled to pad interconnects (e.g., pad interconnects located in the encapsulation layer 406b) through a plurality of solder interconnects 205b. The passive device 109b may be coupled to pad interconnects (e.g., pad interconnects located in the encapsulation layer 406b) through a plurality of solder interconnects 209b.

The metallization portion 408 is coupled to the encapsulation layer 406b. The encapsulation layer 406b is located vertically between the metallization portion 102b and the metallization portion 408. The metallization portion 408 may include at least one dielectric layer 480 and a plurality of metallization interconnects 482. The plurality of metallization interconnects 482 are coupled to some of the via interconnects from the plurality of via interconnects 460b. The plurality of metallization interconnects 482 are coupled to some of the pad interconnects in the encapsulation layer 406b.

The metallization portion 102b vertically overlaps with only part of the metallization portion 408. The lateral area of the metallization portion 408 is greater than the lateral area of the metallization portion 102b. The encapsulation layer 110 is coupled to a surface of the metallization portion 408. The encapsulation layer 110 is coupled to a side surface of the encapsulation layer 406b and/or a side surface of the metallization portion 102b.

The plurality of pillar interconnects 484 are coupled to the plurality of metallization interconnects 482. The metallization portion 408 is coupled to the plurality of board interconnects 194 through the plurality of pillar interconnects 484 and a plurality of solder interconnects 196.

As will be further described below, the package 100 and/or the package 400 provides a package that can be tested during different stages of the fabrication process, thereby identifying early when a component of a package is defective, which can help avoid fabricating or coupling unnecessary components on the packages.

### Exemplary Passive Devices

FIG. 7 illustrates a cross sectional profile view of a passive device 700 that is configured as a trench capacitor device. The passive device 700 may be an integrated passive device. The passive device 700 may represent any of the passive devices described in the disclosure. For example, the passive device 700 may represent the passive device(s) 105a, 105b, 109a and/or 109b. The passive device 700 may be an integrated passive device (e.g., passive device) that includes multiple trench capacitors (e.g., deep trench capacitors). The passive device 700 may be a means for trench capacitance. The passive device 700 includes a front side and a back side. The front side of the passive device 700 may include the plurality of trench capacitors.

The passive device 700 includes a passive device substrate 702 (e.g., passive device substrate) and a plurality of trench capacitors 705. A plurality of solder interconnects (not shown) may be coupled to the passive device 700. The passive device substrate 702 may include silicon (Si). The passive device substrate 702 may include a plurality of trenches and/or cavities over which capacitors may be formed.

The plurality of trench capacitors 705 includes a trench capacitor 705a and a trench capacitor 705b. In some implementations, the trench capacitor 705a and the trench capacitor 705b may be configured to be part of a same capacitor (e.g., first capacitor, first trench capacitor). In some implementations, the trench capacitor 705a and the trench capacitor 705b may be configured to be coupled to and/or part of a first power distribution network (PDN). The trench capacitor 705a and the trench capacitor 705b may be configured to be part of a first electrical path for a first power for a package. The trench capacitor 705a and the trench capacitor 705b may be configured to be coupled to integrated device(s).

As shown in FIG. 7, the passive device 700 includes the passive device substrate 702, an oxide layer 704, a first electrically conductive layer 706, a dielectric layer 708, a second electrically conductive layer 710 and a dielectric layer 780. The first electrically conductive layer 706 and/or the second electrically conductive layer 710 may include polysilicon. The oxide layer 704 and/or the dielectric layer 708 may include SiO₂ (e.g., low-pressure chemical vapor deposition (LPCVD) SiO₂) or Si₃N₄ (e.g., LPCVD Si₃N₄). Portions of the oxide layer 704, the first electrically conductive layer 706, the dielectric layer 708, and the second electrically conductive layer 710 may be located in trenches and/or cavities of the passive device substrate 702. The dielectric layer 780 may include silicon nitride. It is noted that a passive device substrate 702 may be considered to have a trench or a cavity, even if the trench or the cavity is filled with one or more materials.

The trench capacitor 705a (e.g., first trench capacitor, first capacitor, means for first trench capacitance) may be defined by (i) a first portion of the oxide layer 704, (ii) a first portion of the first electrically conductive layer 706, (iii) a first portion of the dielectric layer 708, and (iv) a first portion of the second electrically conductive layer 710 that are located in a trench (e.g., first trench) of the passive device substrate 702.

The trench capacitor 705b (e.g., second trench capacitor, second capacitor, means for second trench capacitance) may be defined by (i) a second portion of the oxide layer 704, (ii) a second portion of the first electrically conductive layer 706, (iii) a second portion of the dielectric layer 708, and (iv) a second portion of the second electrically conductive layer 710 that are located in a trench (e.g., second trench) of the passive device substrate 702. It is noted that trench capacitor 705b may be part of a same capacitor as the trench capacitor 705a. That is, the trench capacitor 705a and the trench capacitor 705b may be configured to be electrically coupled together to form a capacitor (e.g., first capacitor) with a greater capacitance. The passive device 700 may also optionally include a post interconnect 799 that is coupled to the first electrically conductive layer 706. The passive device may also include other post interconnects that are coupled to other second electrically conductive layer 710.

The passive device 700 also includes an interconnect 709, an interconnect 792, and an interconnect 794. The interconnect 709 is coupled to the interconnect 792 and the interconnect 794. The interconnect 709 may be a through substrate via that extends through the passive device substrate 702. The interconnect 792 may be a pad interconnect. The interconnect 794 may be a pad interconnect. The interconnect 792 may be located on the front side of the passive device 700. The interconnect 794 may be located on the back side of the passive device 700. The interconnect 709 may be a through passive device substrate interconnect. The passive device may include at least one through passive device substrate interconnect. The interconnect 792 may be part of a plurality of metallization interconnects (e.g., plurality of front side metallization interconnects). The interconnect 794 may be part of a plurality of metallization interconnects (e.g., plurality of back side metallization interconnects). The passive device 700 may also optionally include a post interconnect 793 and a post interconnect 795. The post interconnect 793 may be coupled to the interconnect 792. The post interconnect 795 may be coupled to the interconnect 794. In some implementations, the post interconnect 795 may include copper. In some implementations, the post interconnect 795 may include a copper layer, a nickel layer and another copper layer. The post interconnect 795 may be part of a plurality of post interconnects. The post interconnect 799 may be part of a plurality of post interconnects. The post interconnect 793 may be part of a plurality of post interconnects. A plurality of solder interconnects may be coupled to the post interconnect 793, the post interconnect 795 and/or the post interconnect 799. A post interconnect may be similar to a pillar interconnect.

As mentioned above, the passive device 700 includes a plurality of bump interconnects. The plurality of bump interconnects for the passive device 700 may include the post interconnect 793, the post interconnect 795 and/or the post interconnect 799. In some implementations, the plurality of bump interconnects for the passive device 700 may include the solder interconnects that may be coupled to the post interconnect 793, the post interconnect 795, and/or the post interconnect 799. The passive device 700 may include a plurality of front side bump interconnects and/or a plurality of back side bump interconnects. In some implementations, the post interconnect 799 and/or the post interconnect 793 may be part of a plurality of front side bump interconnects. In some implementations, the post interconnect 795 may be part of a plurality of back side bump interconnects. The plurality of bump interconnects may have different sizes, shapes and/or heights. For example, the plurality of bump interconnects may include bump interconnects with different widths and/or minimum widths.

An integrated device (e.g., 101a, 101a) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100, 400) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Sub-package

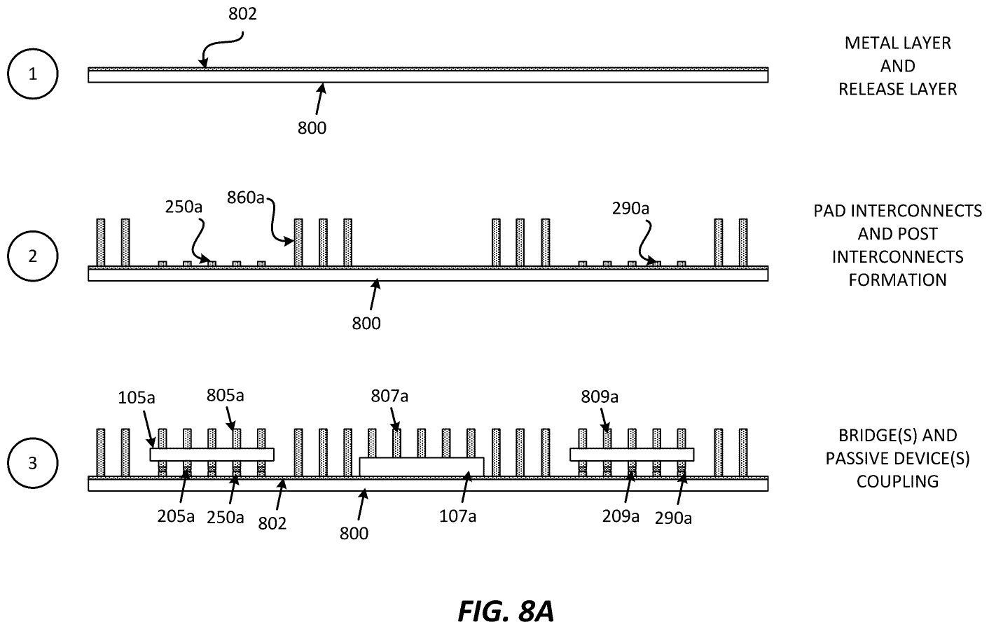

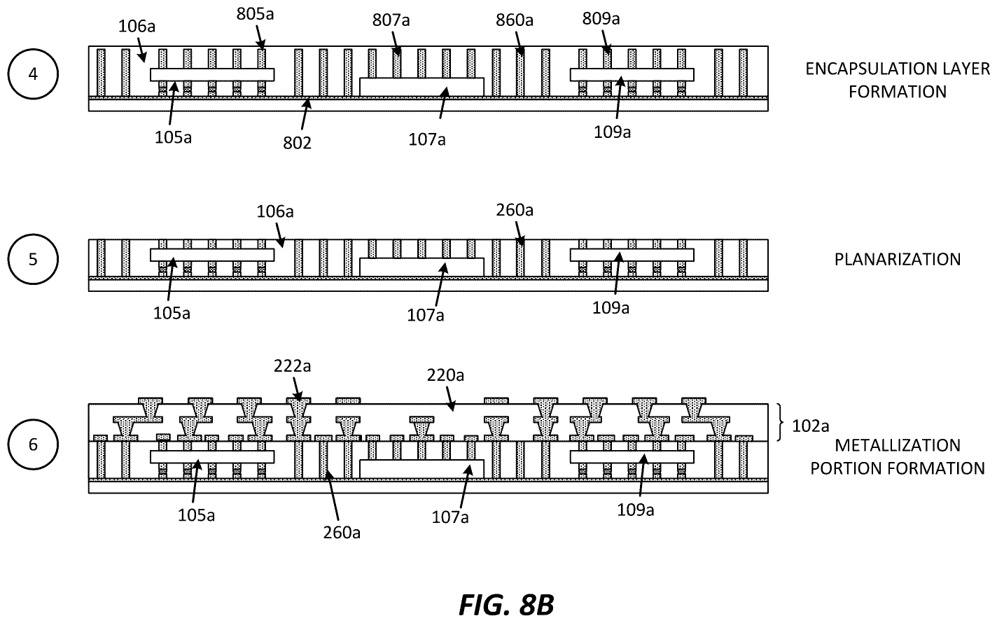

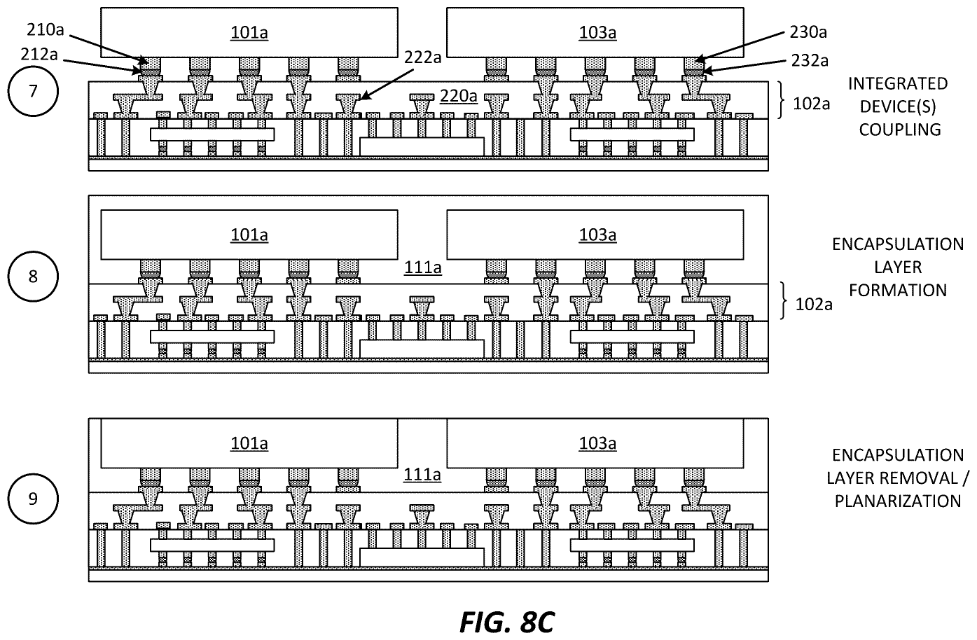

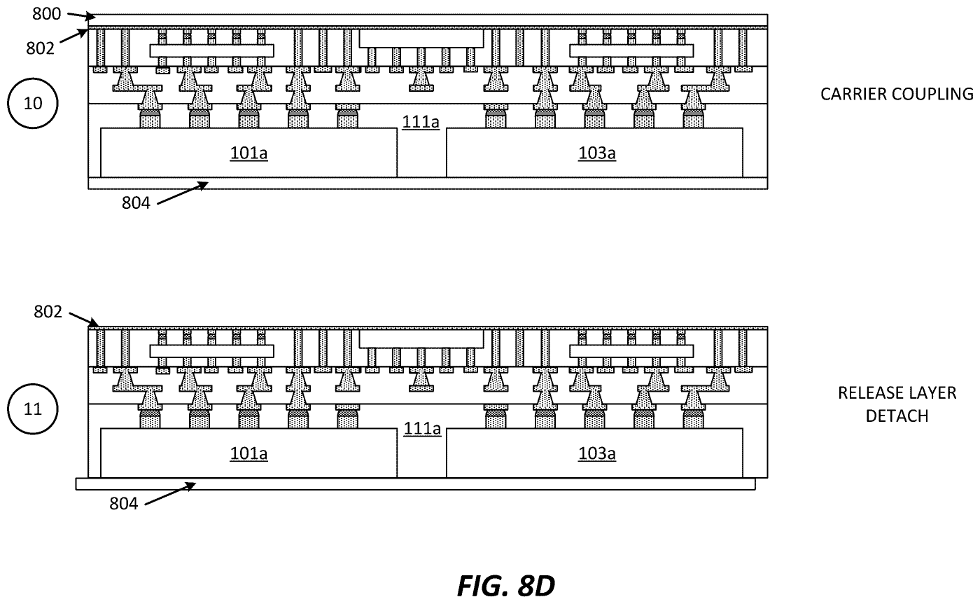

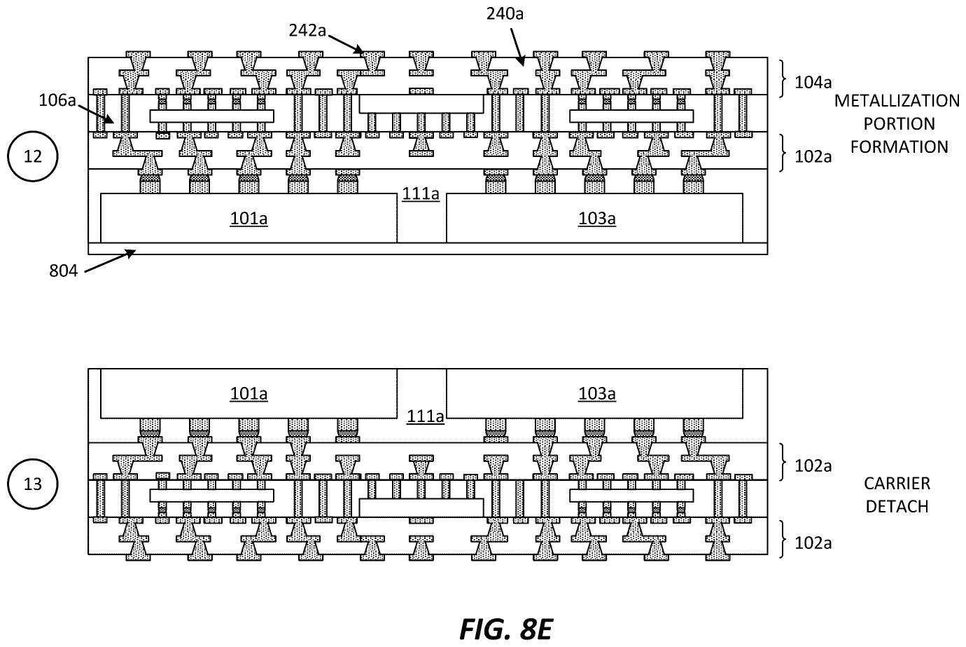

In some implementations, fabricating a sub-package includes several processes. FIG. 8A-8E illustrate an exemplary sequence for providing or fabricating a sub-package. In some implementations, the sequence of FIG. 8A-8E may be used to provide or fabricate the sub-package 200. However, the process of FIG. 8A-8E may be used to fabricate any of the sub-packages described in the disclosure.

It should be noted that the sequence of FIG. 8A-8E may combine one or more stages in order to simplify and/or clarify the sequence for providing or fabricating a sub-package. In some implementations, the order of the processes may be changed or modified. In some implementations, one or more of processes may be replaced or substituted without departing from the scope of the disclosure.

Stage 1, as shown in FIG. 8A, illustrates a state after a release layer 800 and a metal layer 802 are provided. The release layer 800 may be a carrier. The metal layer 802 may be coupled to a surface of the release layer 800. The metal layer 802 may be a seed layer. The metal layer 802 may include copper (Cu).

Stage 2 illustrates a state after a plurality of post interconnects 860a, a plurality of pad interconnects 250a and/or a plurality of pad interconnects 290a are formed on the metal layer 802. A plating process may be used to form the plurality of post interconnects 860a, the plurality of pad interconnects 250a and/or the plurality of pad interconnects 290a. Different implementations may form the plurality of post interconnects 860a with different heights and/or width.

Stage 3 illustrates a state after the passive device 105a, the passive device 109a and the bridge 107a are coupled to the metal layer 802 and the release layer 800. The passive device 105a may be coupled to the plurality of pad interconnects 250a through a plurality of solder interconnects 205a (e.g., by using a solder reflow process). The passive device 105a may include a plurality of post interconnects 805a. The passive device 109a may be coupled to the plurality of pad interconnects 290a through a plurality of solder interconnects 209a (e.g., by using a solder reflow process). The passive device 109a may include a plurality of post interconnects 809a. The bridge 107a is coupled to the metal layer 802. For example, a back side of the bridge 107a may be coupled to the metal layer 802 through an adhesive (not shown). The bridge 107a may include a plurality of post interconnects 807a.

Stage 4, as shown in FIG. 8B, illustrates a state after the encapsulation layer 106 is formed. The encapsulation layer 106a may at least partially encapsulate the passive device 105a, the bridge 107a, the passive device 109a, the plurality of post interconnects 860a, the plurality of post interconnects 805a, the plurality of post interconnects 807a and the plurality of post interconnects 809a. The encapsulation layer 106a may include a mold, a resin, an epoxy and/or a filler. The encapsulation layer 106a may be provided by using a compression and transfer molding process, a sheet molding process, or a liquid molding process. The encapsulation layer 106a may be over molded.

Stage 5 illustrates a state after planarization of the encapsulation layer 106a and the plurality of via interconnects 260a. Planarization may include removing portions of the encapsulation layer 106a and portions of the plurality of via interconnects 260a. The plurality of via interconnects 260a may represent the plurality of post interconnects 860a, the plurality of post interconnects 805a, the plurality of post interconnects 807a and/or the plurality of post interconnects 809a. A polishing process and/or a grinding process may be used to perform planarization.

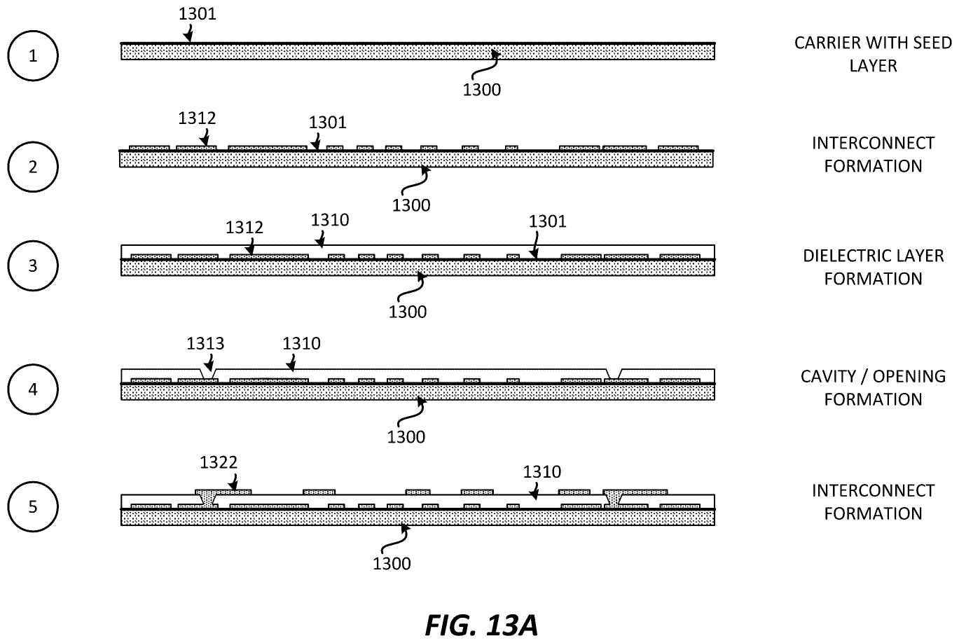

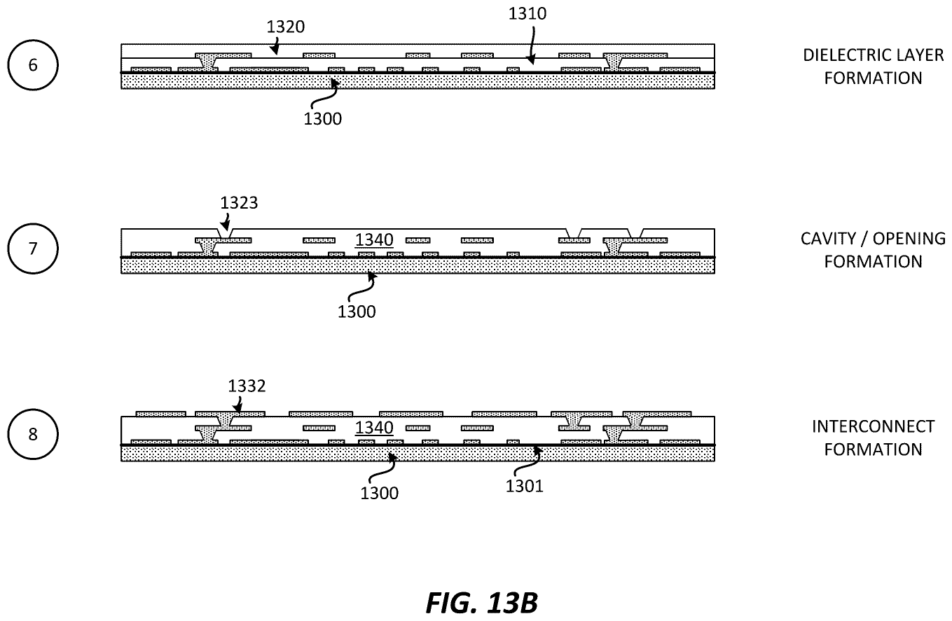

Stage 6 illustrates a state after a metallization portion 102a is formed and coupled to the encapsulation layer 106a and the plurality of via interconnects 260a. The metallization portion 102a may include at least one dielectric layer 220a and a plurality of metallization interconnects 222a. The plurality of metallization interconnects 222a may be coupled to the plurality of via interconnects 260a. An example of forming a metallization portion is illustrated and described below in at least FIG. 13A-13B.

Stage 7, as shown in FIG. 8C, illustrates a state after an integrated device 101a and an integrated device 103a are coupled to the metallization portion 102a. The integrated device 101a may be coupled to the plurality of metallization interconnects 222a of the metallization portion 102a through a plurality of pillar interconnects 210a and the plurality of solder interconnects 212a by using a solder reflow process. The integrated device 103a may be coupled to the plurality of metallization interconnects 222a of the metallization portion 102a through a plurality of pillar interconnects 230a and the plurality of solder interconnects 232a by using a solder reflow process.

Stage 8 illustrates a state after the encapsulation layer 111a is formed over the metallization portion 102a, the integrated device 101a and the integrated device 103a. The encapsulation layer 111a may at least partially encapsulate the integrated device 101a and the integrated device 103a. The encapsulation layer 111a may include a mold, a resin, an epoxy and/or a filler. The encapsulation layer 111a may be provided by using a compression and transfer molding process, a sheet molding process, or a liquid molding process. The encapsulation layer 111a may be over molded.

Stage 9 illustrates a state after planarization of the encapsulation layer 111a. Planarization may include removing portions of the encapsulation layer 111a. Planarization may also include removing portions of the back side of the integrated device 101a and/or the back side of the integrated device 103a. A polishing process and/or a grinding process may be used to perform planarization.

Stage 10, as shown in FIG. 8D, illustrates a state after a carrier 804 is coupled to the encapsulation layer 111a, the integrated device 101a and the integrated device 103a. In some implementations, the carrier 804 may include a glass or silicon. In some implementations, an adhesive may be used to couple the carrier 804 to the encapsulation layer 111a, the integrated device 101a and/or the integrated device 103a.

Stage 11 illustrates a state after the release layer 800 is detached and/or removed. In some implementations, the sub-package 500 (as described in FIG. 5) may be fabricated once the metal layer 803 is removed and/or etched out, and the carrier 804 is detached. In some implementations, the devices may be tested to ensure that devices are working properly. This will help in improving the yield when fabricating sub-packages and/or packages comprising sub-packages, since defective sub-packages will be discarded and only functioning sub-packages will be placed in packages. Better yields may mean reduced costs of the packages. In addition, by fabricating sub-packages, which are smaller, more compact and/or have higher interconnect densities, and then combining them with other sub-packages, higher density interconnects may be achieved for the bigger packages, while still keeping the fabrication yields as high as possible.

Stage 12, as shown in FIG. 8E, illustrates a state after a metallization portion 104a is formed and coupled to the encapsulation layer 106a, the plurality of via interconnects 260a, the plurality of pad interconnects 250a and/or the plurality of pad interconnects 290a. The metallization portion 104a may include at least one dielectric layer 240a and a plurality of metallization interconnects 242a. A portion of the metal layer 802 may be considered part of the plurality of metallization interconnects 242a. An example of forming a metallization portion is illustrated and described below in at least FIG. 13A-13B.

Stage 13 illustrates a state after the carrier 804 is decoupled and/or detached from the encapsulation layer 111a, the integrated device 101a and/or the integrated device 103a. Stage 13 may illustrates an example of the sub-package 200. In some implementations, the sub-package 200 is fabricated as part of one or more wafers, and the wafer(s) is/are singulated to form individual sub-packages.

### Exemplary Flow Diagram of a Method for Fabricating a Sub-package

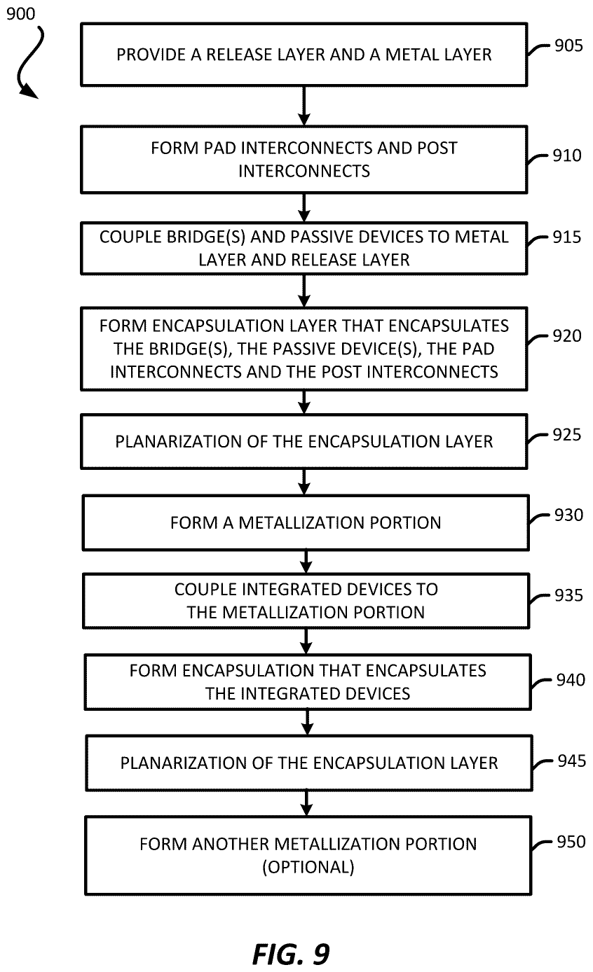

In some implementations, fabricating a sub-package includes several processes. FIG. 9 illustrates an exemplary flow diagram of a method 900 for providing or fabricating a sub-package. In some implementations, the method 900 of FIG. 9 may be used to provide or fabricate any of the sub-packages (e.g., 200, 300, 500, 600) described in the disclosure.

It should be noted that the method 900 of FIG. 9 may combine one or more processes in order to simplify and/or clarify the method for providing or fabricating a sub-package. In some implementations, the order of the processes may be changed or modified. FIG. 9 will be described with respect to FIG. 8A-8E.

The method provides (at 905) a release layer and a metal layer. Stage 1 of FIG. 8A, illustrates and describes an example of a state after a release layer 800 and a metal layer 802 are provided. The release layer 800 may be a carrier. The metal layer 802 may be coupled to a surface of the release layer 800. The metal layer 802 may be a seed layer. The metal layer 802 may include copper (Cu).

The method forms (at 910) a plurality of post interconnects and/or a plurality of post interconnects. Stage 2 of FIG. 8A, illustrates and describes an example of a state after a plurality of post interconnects 860a, a plurality of pad interconnects 250a and/or a plurality of pad interconnects 290a are formed on the metal layer 802. A plating process may be used to form the plurality of post interconnects 860a, the plurality of pad interconnects 250a and/or the plurality of pad interconnects 290a. Different implementations may form the plurality of post interconnects 860a with different heights and/or width.

The method couples (at 915) at least one bridge and/or at least passive device to the metal layer and/or the release layer. Stage 3 of FIG. 8A, illustrates and describes an example of a state after the passive device 105a, the passive device 109a and the bridge 107a are coupled to the metal layer 802 and the release layer 800. The passive device 105a may be coupled to the plurality of pad interconnects 250a through a plurality of solder interconnects 205a (e.g., by using a solder reflow process). The passive device 105a may include a plurality of post interconnects 805a. The passive device 109a may be coupled to the plurality of pad interconnects 290a through a plurality of solder interconnects 209a (e.g., by using a solder reflow process). The passive device 109a may include a plurality of post interconnects 809a. The bridge 107a is coupled to the metal layer 802. For example, a back side of the bridge 107a may be coupled to the metal layer 802 through an adhesive (not shown). The bridge 107a may include a plurality of post interconnects 807a.

The method forms (at 920) an encapsulation layer. Stage 4 of FIG. 8B, illustrates and describes an example of a state after the encapsulation layer 106 is formed. The encapsulation layer 106a may at least partially encapsulate the passive device 105a, the bridge 107a, the passive device 109a, the plurality of post interconnects 860a, the plurality of post interconnects 805a, the plurality of post interconnects 807a and the plurality of post interconnects 809a. The encapsulation layer 106a may include a mold, a resin, an epoxy and/or a filler. The encapsulation layer 106a may be provided by using a compression and transfer molding process, a sheet molding process, or a liquid molding process. The encapsulation layer 106a may be over molded.

The method planarizes (at 925) the encapsulation layer. Stage 5 of FIG. 8B, illustrates and describes an example of a state after planarization of the encapsulation layer 106a and the plurality of via interconnects 260a. Planarization may include removing portions of the encapsulation layer 106a and portions of the plurality of via interconnects 260a. The plurality of via interconnects 260a may represent the plurality of post interconnects 860a, the plurality of post interconnects 805a, the plurality of post interconnects 807a and/or the plurality of post interconnects 809a. A polishing process and/or a grinding process may be used to perform planarization.

The method forms (at 930) a metallization portion. In some implementations, the metallization portion may be coupled to the encapsulation layer. Stage 6 of FIG. 8B, illustrates and describes an example of a state after a metallization portion 102a is formed and coupled to the encapsulation layer 106a and the plurality of via interconnects 260a. The metallization portion 102a may include at least one dielectric layer 220a and a plurality of metallization interconnects 222a. The plurality of metallization interconnects 222a may be coupled to the plurality of via interconnects 260a. An example of forming a metallization portion is illustrated and described below in at least FIG. 13A-13B.

The method couples (at 935) a plurality of integrated devices to the metallization portion. Stage 7 of FIG. 8C, illustrates and describes an example of a state after an integrated device 101a and an integrated device 103a are coupled to the metallization portion 102a. The integrated device 101a may be coupled to the plurality of metallization interconnects 222a of the metallization portion 102a through a plurality of pillar interconnects 210a and the plurality of solder interconnects 212a by using a solder reflow process. The integrated device 103a may be coupled to the plurality of metallization interconnects 222a of the metallization portion 102a through a plurality of pillar interconnects 230a and the plurality of solder interconnects 232a by using a solder reflow process.

The method forms (at 940) an encapsulation layer that at least partially encapsulates the integrated devices. Stage 8 of FIG. 8C, illustrates and describes an example of a state after the encapsulation layer 111a is formed over the metallization portion 102a, the integrated device 101a and the integrated device 103a. The encapsulation layer 111a may at least partially encapsulate the integrated device 101a and the integrated device 103a. The encapsulation layer 111a may include a mold, a resin, an epoxy and/or a filler. The encapsulation layer 111a may be provided by using a compression and transfer molding process, a sheet molding process, or a liquid molding process. The encapsulation layer 111a may be over molded.

The method planarizes (at 945) the encapsulation layer. Stage 9 of FIG. 8C, illustrates and describes an example of a state after planarization of the encapsulation layer 111a. Planarization may include removing portions of the encapsulation layer 111a. Planarization may also include removing portions of the back side of the integrated device 101a and/or the back side of the integrated device 103a. A polishing process and/or a grinding process may be used to perform planarization.

In some implementations, after the planarization process, the method may couple a carrier to the encapsulation layer and integrated devices. Stage 10 of FIG. 8D, illustrates and describes an example of a state after a carrier 804 is coupled to the encapsulation layer 111a, the integrated device 101a and the integrated device 103a. In some implementations, the carrier 804 may include a glass or silicon. In some implementations, an adhesive may be used to couple the carrier 804 to the encapsulation layer 111a, the integrated device 101a and/or the integrated device 103a. Next, the method may remove the release layer. Stage 11 of FIG. 8D, illustrates and describes an example of a state after the release layer 800 is detached and/or removed. In some implementations, the sub-package 500 (as described in FIG. 5) may be fabricated once the metal layer 803 is removed and/or etched out, and the carrier 804 is detached. In some implementations, the devices may be tested to ensure that devices are working properly. This will help in improving the yield when fabricating sub-packages and/or packages comprising sub-packages, since defective sub-packages will be discarded and only functioning sub-packages will be placed in bigger packages. Better yields may mean reduced costs of the packages. In addition, by fabricating sub-packages, which are smaller, more compact and/or have higher interconnect densities, and then combining them with other sub-packages, higher density interconnects may be achieved for the bigger packages, while still keeping the fabrication yields as high as possible.

In some implementations, the method may optionally form (at 950) another metallization portion. Stage 12 of FIG. 8E, illustrates and describes an example of a state after a metallization portion 104a is formed and coupled to the encapsulation layer 106a, the plurality of via interconnects 260a, the plurality of pad interconnects 250a and/or the plurality of pad interconnects 290a. The metallization portion 104a may include at least one dielectric layer 240a and a plurality of metallization interconnects 242a. A portion of the metal layer 802 may be considered part of the plurality of metallization interconnects 242a. An example of forming a metallization portion is illustrated and described below in at least FIG. 13A-13B.

After the metallization portion is formed, the method may remove the carrier. Stage 13 of FIG. 8E, illustrates and describes an example of a state after the carrier 804 is decoupled and/or detached from the encapsulation layer 111a, the integrated device 101a and/or the integrated device 103a. Stage 13 of FIG. 8E, may illustrate an example of the sub-package 200. In some implementations, the sub-package 200 is fabricated as part of one or more wafers, and the wafer(s) is/are singulated to form individual sub-packages.

### Exemplary Sequence for Fabricating a Package

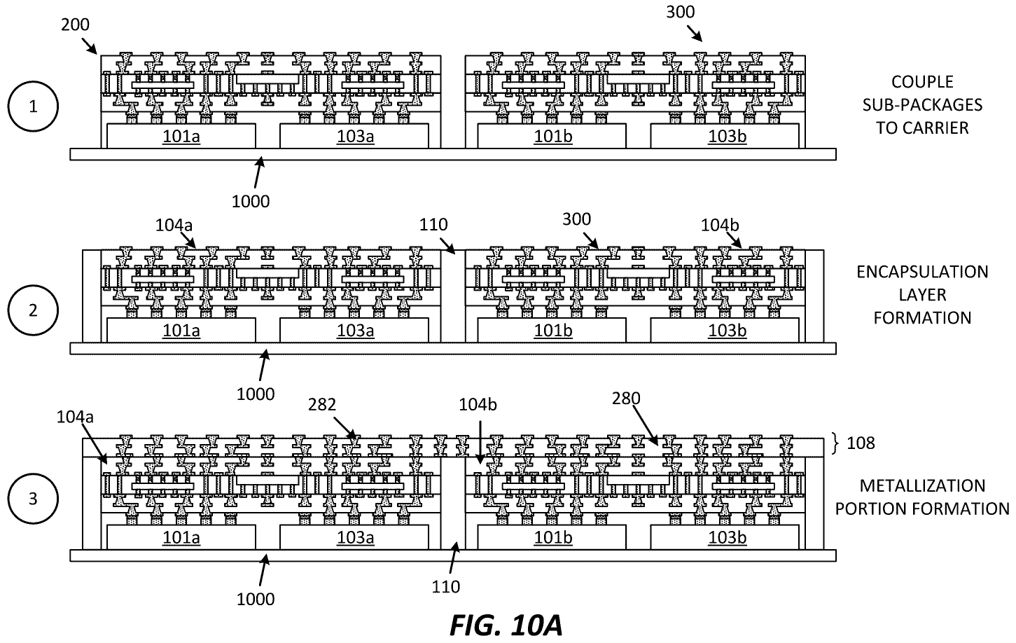

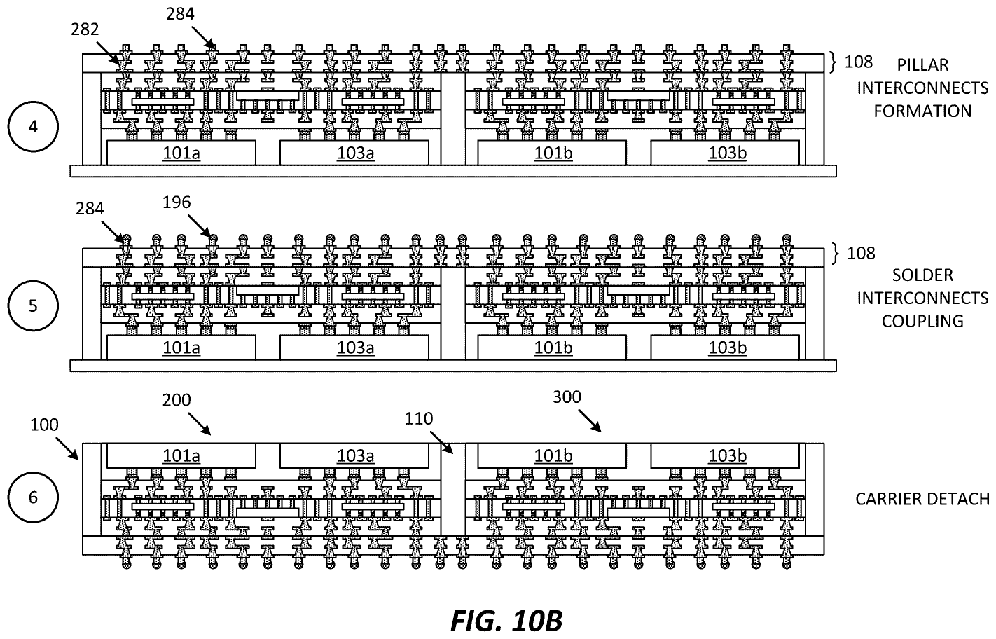

In some implementations, fabricating a package includes several processes. FIG. 10A-10B illustrate an exemplary sequence for providing or fabricating a package. In some implementations, the sequence of FIG. 10A-10B may be used to provide or fabricate the package 100. However, the process of FIG. 10A-10B may be used to fabricate any of the packages described in the disclosure.

It should be noted that the sequence of FIG. 10A-10B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 10A, illustrates a state after a sub-package 200 and a sub-package 300 are provided, placed and/or coupled to a carrier 1000. The carrier 1000 may include glass. An adhesive may be used to place and couple the sub-package 200 and the sub-package 300 to the carrier 1000. The back side of the sub-package 200 and the back side of the sub-package 300 may be coupled to the carrier 1000.

Stage 2 illustrates a state after an encapsulation layer 110 is formed over the carrier 1000 and the sub-package 200 and the sub-package 300. The encapsulation layer 110 may at least partially encapsulate the sub-package 200 and/or the sub-package 300. The encapsulation layer 110 may include a mold, a resin, an epoxy and/or a filler. The encapsulation layer 110 may be provided by using a compression and transfer molding process, a sheet molding process, or a liquid molding process. In some implementations, the encapsulation layer 110 may be over molded and a planarization process may be performed.

Stage 3 illustrates a state after a metallization portion 108 is formed and coupled to the metallization portion 104a of the sub-package 200, the metallization portion 104b of the sub-package 300 and the encapsulation layer 110. The metallization portion 108 may include at least one dielectric layer 280 and a plurality of metallization interconnects 282. The plurality of metallization interconnects 282 may be coupled to the plurality of metallization interconnects 242a and the plurality of metallization interconnects 242b. An example of forming a metallization portion is illustrated and described below in at least FIG. 13A-13B.

Stage 4, as shown in FIG. 10B, illustrates a state after a plurality of pillar interconnects 284 are formed and coupled to the plurality of metallization interconnects 282. A plating process may be used to form the plurality of pillar interconnects 284. In some implementations, the plurality of pillar interconnects 284 may be considered to be part of the plurality of metallization interconnects 282.

Stage 5 illustrates a state after a plurality of solder interconnects 196 are formed and coupled to the plurality of pillar interconnects 284. In some implementations, the plurality of solder interconnects 196 may be coupled to the plurality of metallization interconnects 282. A solder reflow process may be used to form and couple the plurality of solder interconnects 196 to the plurality of pillar interconnects 284. In some implementations, the packages may be tested to ensure that packages are working properly.

Stage 6 illustrates a state after the carrier 1000 has been detached from the sub-package 200, the sub-package 300 and the encapsulation layer 110. Stage 6 may illustrate the package 100 of FIG. 1. It is noted that in some implementations, one or more sub-packages (e.g., 200, 300) may not be distinguishable from the package and/or other sub-packages.

### Exemplary Sequence for Fabricating a Package

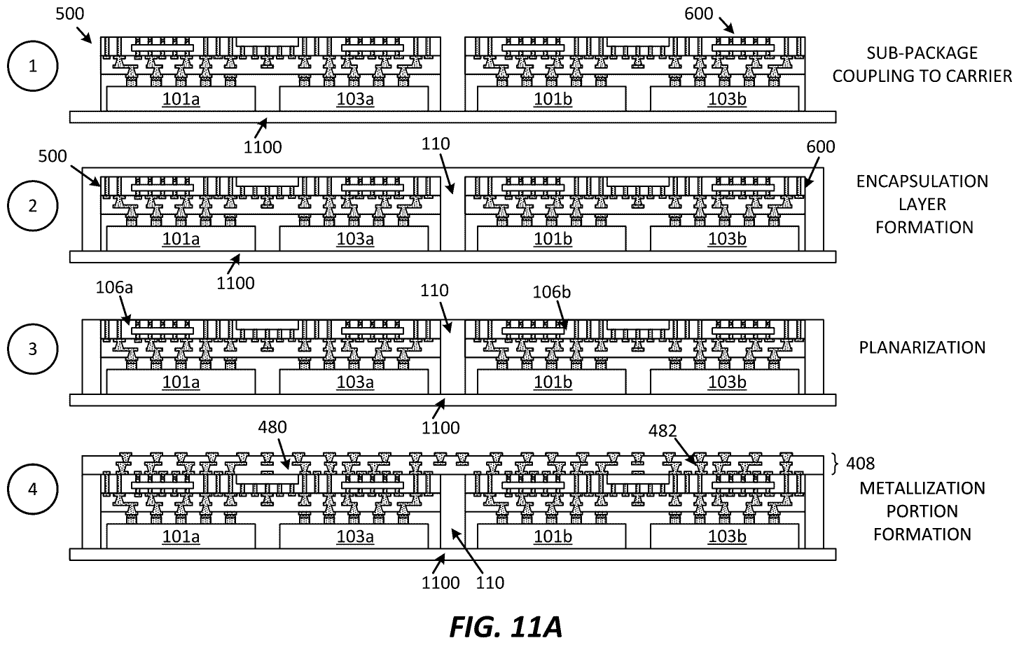

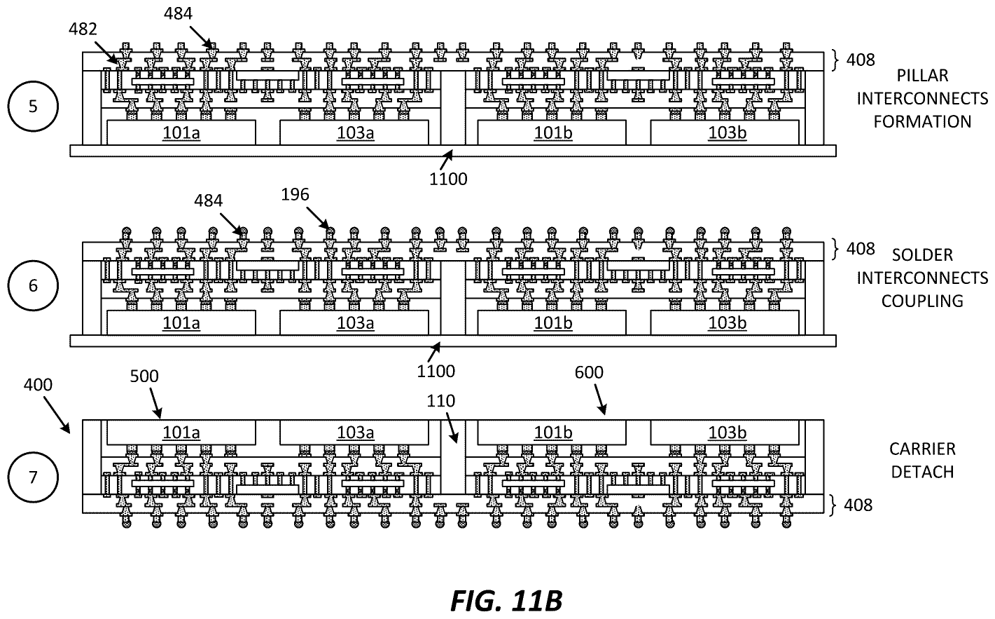

In some implementations, fabricating a package includes several processes. FIG. 11A-11B illustrate an exemplary sequence for providing or fabricating a package. In some implementations, the sequence of FIG. 11A-11B may be used to provide or fabricate the package 400. However, the process of FIG. 11A-11B may be used to fabricate any of the packages described in the disclosure.

It should be noted that the sequence of FIG. 11A-11B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 11A, illustrates a state after a sub-package 500 and a sub-package 600 are provided, placed and/or coupled to a carrier 1100. The carrier 1100 may include glass. An adhesive may be used to place and couple the sub-package 500 and the sub-package 600 to the carrier 1100. The back side of the sub-package 500 and the back side of the sub-package 600 may be coupled to the carrier 1100.

Stage 2 illustrates a state after an encapsulation layer 110 is formed over the carrier 1100 and the sub-package 500 and the sub-package 500. The encapsulation layer 110 may at least partially encapsulate the sub-package 500 and/or the sub-package 600. The encapsulation layer 110 may include a mold, a resin, an epoxy and/or a filler. The encapsulation layer 110 may be provided by using a compression and transfer molding process, a sheet molding process, or a liquid molding process.

Stage 3 illustrates a state after planarization. The planarization process may include removing portions of the encapsulation layer 110, portions of the encapsulation layer 406a and/or the encapsulation layer 406b. Planarization may include a polishing process and/or a grinding process.

Stage 4 illustrates a state after a metallization portion 408 is formed and coupled to the encapsulation layer 406a of the sub-package 500, the encapsulation layer 406b of the sub-package 600 and the encapsulation layer 110. The metallization portion 408 may include at least one dielectric layer 480 and a plurality of metallization interconnects 482. The plurality of metallization interconnects 482 may be coupled to the plurality of via interconnects 460a and the plurality of via interconnects 460b. An example of forming a metallization portion is illustrated and described below in at least FIG. 13A-13B.

Stage 5, as shown in FIG. 11B, illustrates a state after a plurality of pillar interconnects 484 are formed and coupled to the plurality of metallization interconnects 482. A plating process may be used to form the plurality of pillar interconnects 484. In some implementations, the plurality of pillar interconnects 484 may be considered to be part of the plurality of metallization interconnects 482.

Stage 6 illustrates a state after a plurality of solder interconnects 196 are formed and coupled to the plurality of pillar interconnects 484. In some implementations, the plurality of solder interconnects 196 may be coupled to the plurality of metallization interconnects 482. A solder reflow process may be used to form and couple the plurality of solder interconnects 196 to the plurality of pillar interconnects 484. In some implementations, the packages may be tested to ensure that packages are working properly.

Stage 7 illustrates a state after the carrier 1100 has been detached from the sub-package 500, the sub-package 600 and the encapsulation layer 110. Stage 7 may illustrate the package 400 of FIG. 4. It is noted that in some implementations, one or more sub-packages (e.g., 500, 600) may not be distinguishable from the package and/or other sub-packages.

### Exemplary Flow Diagram of a Method for Fabricating a Package

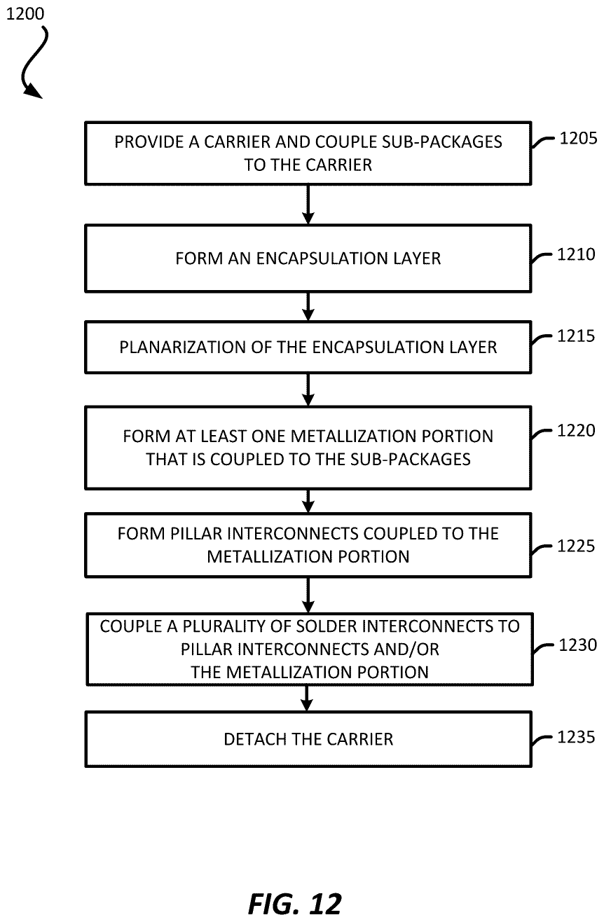

In some implementations, fabricating a package includes several processes. FIG. 12 illustrates an exemplary flow diagram of a method 1200 for providing or fabricating a package. In some implementations, the method 1200 of FIG. 12 may be used to provide or fabricate any of the packages described in the disclosure.

It should be noted that the method 1200 of FIG. 12 may combine one or more processes in order to simplify and/or clarify the method for providing or fabricating a package. In some implementations, the order of the processes may be changed or modified. FIG. 12 will be described with respect to FIG. 11A-11B. However, the method 1200 of FIG. 12 may also be applicable to FIG. 10A-10B.

The method provides (at 1305) a carrier and couples sub-packages to the carrier. Stage 1 of FIG. 11A, illustrates and describes an example of a state after a sub-package 500 and a sub-package 600 are provided, placed and/or coupled to a carrier 1100. The carrier 1100 may include glass. An adhesive may be used to place and couple the sub-package 500 and the sub-package 600 to the carrier 1100. The back side of the sub-package 500 and the back side of the sub-package 600 may be coupled to the carrier 1100.

The method forms (at 1210) an encapsulation layer. Stage 2 of FIG. 11A, illustrates and describes an example of a state after an encapsulation layer 110 is formed over the carrier 1100 and the sub-package 500 and the sub-package 500. The encapsulation layer 110 may at least partially encapsulate the sub-package 500 and/or the sub-package 600. The encapsulation layer 110 may include a mold, a resin, an epoxy and/or a filler. The encapsulation layer 110 may be provided by using a compression and transfer molding process, a sheet molding process, or a liquid molding process.

The method planarizes (at 1215) the encapsulation layer. Stage 3 of FIG. 11A, illustrates and describes an example of a state after planarization. The planarization process may include removing portions of the encapsulation layer 110, portions of the encapsulation layer 406a and/or the encapsulation layer 406b. Planarization may include a polishing process and/or a grinding process.

The method forms (at 1220) a metallization portion that is coupled to at least one sub-package. Stage 4 of FIG. 11A, illustrates and describes an example of a state after a metallization portion 408 is formed and coupled to the encapsulation layer 406a of the sub-package 500, the encapsulation layer 406b of the sub-package 600 and the encapsulation layer 110. The metallization portion 408 may include at least one dielectric layer 480 and a plurality of metallization interconnects 482. The plurality of metallization interconnects 482 may be coupled to the plurality of via interconnects 460a and the plurality of via interconnects 460b. An example of forming a metallization portion is illustrated and described below in at least FIG. 13A-13B.

The method forms (at 1225) a plurality of pillar interconnects. Stage 5 of FIG. 11B, illustrates and describes an example of a state after a plurality of pillar interconnects 484 are formed and coupled to the plurality of metallization interconnects 482. A plating process may be used to form the plurality of pillar interconnects 484. In some implementations, the plurality of pillar interconnects 484 may be considered to be part of the plurality of metallization interconnects 482.

The method couples (at 1230) a plurality of solder interconnects to the pillar interconnects and/or the metallization portion. Stage 6 of FIG. 11B, illustrates and describes an example of a state after a plurality of solder interconnects 196 are formed and coupled to the plurality of pillar interconnects 484. In some implementations, the plurality of solder interconnects 196 may be coupled to the plurality of metallization interconnects 482. A solder reflow process may be used to form and couple the plurality of solder interconnects 196 to the plurality of pillar interconnects 484.

The method detaches (at 1235) the carrier. Stage 7 of FIG. 11B, illustrates and describes an example of a state after the carrier 1100 has been detached from the sub-package 500, the sub-package 600 and the encapsulation layer 110. Stage 7 may illustrate the package 400 of FIG. 4.

### Exemplary Sequence for Fabricating a Metallization Portion

In some implementations, fabricating a substrate includes several processes. FIG. 13A-13B illustrate an exemplary sequence for providing or fabricating a metallization portion. In some implementations, the sequence of FIG. 13A-13B may be used to provide or fabricate the metallization portion 102. However, the process of FIG. 13A-13B may be used to fabricate any of the metallization portions described in the disclosure.

It should be noted that the sequence of FIG. 13A-13B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 13A, illustrates a state after a carrier 1300 is provided. A seed layer 1301 may be located over the carrier 1300. The carrier 1300 may be replaced with other components and/or materials.

Stage 2 illustrates a state after a plurality of interconnects 1312 are formed. The interconnects 1312 may be located over the seed layer 1301. A lithography process, a plating process, a strip process and/or an etching process may be used to form the plurality of interconnects 1312. The interconnects 1312 may represent at least some of the interconnects from the plurality of metallization interconnects 122.

Stage 3 illustrates a state after a dielectric layer 1310 is formed over the carrier 1300, the seed layer 1301 and the plurality of interconnects 1312. A deposition and/or lamination process may be used to form the dielectric layer 1310. The dielectric layer 1310 may include prepreg and/or polyimide. The dielectric layer 1310 may include a photo-imageable dielectric. However, different implementations may use different materials for the dielectric layer.

Stage 4 illustrates a state after a plurality of cavities 1313 are formed in the dielectric layer 1310. The plurality of cavities 1313 may be formed using an etching process (e.g., photo etching process), a laser process, an exposure process and/or a development process.

Stage 5 illustrates a state after interconnects 1322 are formed in and over the dielectric layer 1310, including in and over the plurality of cavities 1313. For example, a via, pad and/or traces may be formed. A lithography process, a plating process, a strip process and/or an etching process may be used to form the interconnects.

Stage 6, as shown in FIG. 13B, illustrates a state after a dielectric layer 1320 is formed over the dielectric layer 1310 and the plurality of interconnects 1322. A deposition and/or lamination process may be used to form the dielectric layer 1320. The dielectric layer 1320 may include prepreg and/or polyimide. The dielectric layer 1320 may include a photo-imageable dielectric. However, different implementations may use different materials for the dielectric layer.

Stage 7, illustrates a state after a plurality of cavities 1323 are formed in the dielectric layer 1340. The dielectric layer 1340 may represent the dielectric layer 1310 and/or the dielectric layer 1320. The plurality of cavities 1323 may be formed using an etching process (e.g., photo etching process), a laser process, an exposure process and/or a development process.

Stage 8 illustrates a state after interconnects 1332 are formed in and over the dielectric layer 1340, including in and over the plurality of cavities 1323. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

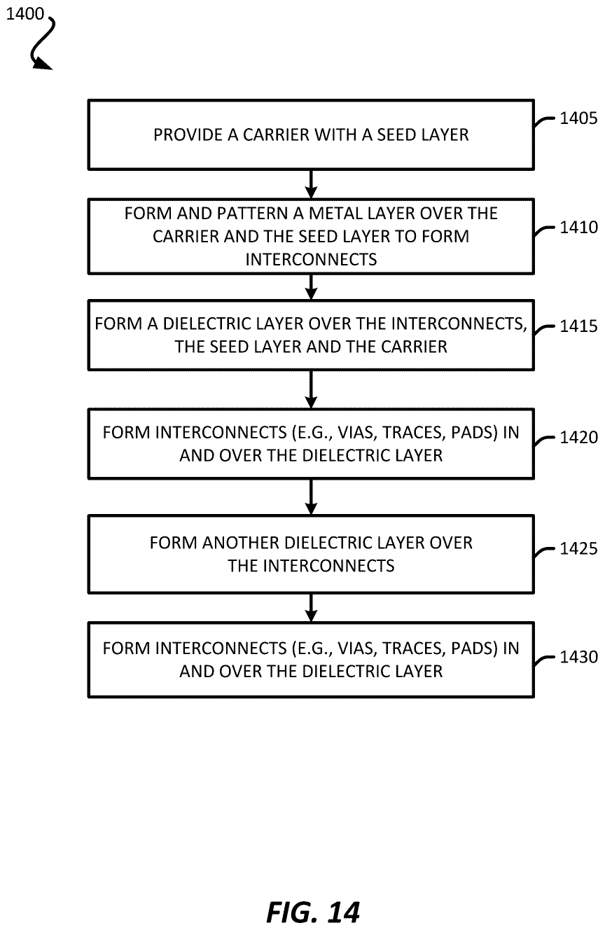

In some implementations, fabricating a substrate includes several processes. FIG. 14 illustrates an exemplary flow diagram of a method 1400 for providing or fabricating a metallization portion. In some implementations, the method 1400 of FIG. 14 may be used to provide or fabricate the metallization portion(s) of the disclosure. For example, the method 1400 of FIG. 14 may be used to fabricate the metallization portion 102.

It should be noted that the method 1400 of FIG. 14 may combine one or more processes in order to simplify and/or clarify the method for providing or fabricating a metallization portion. In some implementations, the order of the processes may be changed or modified.

The method provides (at 1405) a carrier with a seed layer. Stage 1 of FIG. 13A, illustrates and describes an example of a state after a carrier 1300 is provided. A seed layer 1301 may be located over the carrier 1300. The carrier 1300 may be replaced with other components and/or materials.

The method forms and patterns (at 1410) a plurality of interconnects. Stage 2 of FIG. 13A, illustrates and describes an example of a state after a plurality of interconnects 1312 are formed. The interconnects 1312 may be located over the seed layer 1301. A lithography process, a plating process, a strip process and/or an etching process may be used to form the plurality of interconnects 1312. The interconnects 1312 may represent at least some of the interconnects from the plurality of metallization interconnects 122.

The method forms (at 1415) a dielectric layer. Stage 3 of FIG. 13A, illustrates and describes an example of a state after a dielectric layer 1310 is formed over the carrier 1300, the seed layer 1301 and the plurality of interconnects 1312. A deposition and/or lamination process may be used to form the dielectric layer 1310. The dielectric layer 1310 may include prepreg and/or polyimide. The dielectric layer 1310 may include a photo-imageable dielectric. However, different implementations may use different materials for the dielectric layer.

The method forms (at 1420) a plurality of interconnects. Forming a plurality of interconnects may including forming a plurality of cavities in a dielectric layer and a performing a plating process. Stage 4 of FIG. 13A, illustrates and describes an example of a state after a plurality of cavities 1313 are formed in the dielectric layer 1310. The plurality of cavities 1313 may be formed using an etching process (e.g., photo etching process), a laser process, an exposure process and/or a development process.

Stage 5 of FIG. 13A, illustrates and describes an example of a state after interconnects 1322 are formed in and over the dielectric layer 1310, including in and over the plurality of cavities 1313. For example, a via, pad and/or traces may be formed. A lithography process, a plating process, a strip process and/or an etching process may be used to form the interconnects.

The method forms (at 1425) another dielectric layer. Stage 6 of FIG. 13B, illustrates and describes an example of a state after a dielectric layer 1320 is formed over the dielectric layer 1310 and the plurality of interconnects 1322. A deposition and/or lamination process may be used to form the dielectric layer 1320. The dielectric layer 1320 may include prepreg and/or polyimide. The dielectric layer 1320 may include a photo-imageable dielectric. However, different implementations may use different materials for the dielectric layer.

The method forms (at 1430) a plurality of interconnects. Forming a plurality of interconnects may including forming a plurality of cavities in a dielectric layer and a performing a plating process. Stage 7 of FIG. 13B, illustrates and describes an example of a state after a plurality of cavities 1323 are formed in the dielectric layer 1340. The dielectric layer 1340 may represent the dielectric layer 1310 and/or the dielectric layer 1320. The plurality of cavities 1323 may be formed using an etching process (e.g., photo etching process), a laser process, an exposure process and/or a development process.

Stage 8 of FIG. 13B, illustrates and describes an example of a state after interconnects 1332 are formed in and over the dielectric layer 1340, including in and over the plurality of cavities 1323. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

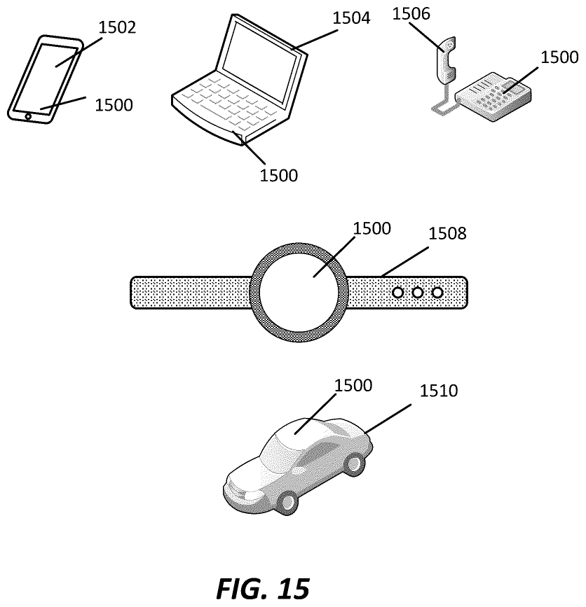

FIG. 15 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1502, a laptop computer device 1504, a fixed location terminal device 1506, a wearable device 1508, or automotive vehicle 1510 may include a device 1500 as described herein. The device 1500 may be, for example, any of the devices and/or integrated circuit (IC) packages described herein. The devices 1502, 1504, 1506 and 1508 and the vehicle 1510 illustrated in FIG. 15 are merely exemplary. Other electronic devices may also feature the device 1500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIG. 1-7, 8A-8E, 9, 10A-10B, 11A-11B, 12, 13A-13B, and 14-15 may be rearranged and/or combined into a single component, process, feature or function or embodied in several components, processes, or functions. Additional elements, components, processes, and/or functions may also be added without departing from the disclosure. It should also be noted FIG. 1-7, 8A-8E, 9, 10A-10B, 11A-11B, 12, 13A-13B, and 14-15 and its corresponding description in the present disclosure is not limited to dies and/or ICs. In some implementations, FIG. 1-7, 8A-8E, 9, 10A-10B, 11A-11B, 12, 13A-13B, and 14-15 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first group and a second group. The first group comprises a first metallization portion; a first integrated device coupled to the first metallization portion; a second integrated device coupled to the first metallization portion; a first encapsulation layer coupled to the first metallization portion; a first passive device located in the first encapsulation layer; and a first bridge located in the first encapsulation layer. The second group comprises a second metallization portion; a third integrated device coupled to the second metallization portion; a fourth integrated device coupled to the second metallization portion; a second encapsulation layer coupled to the second metallization portion; a second passive device located in the second encapsulation layer; and a second bridge located in the second encapsulation layer. The package further comprises a third metallization portion coupled to the first group and the second group; and a third encapsulation layer at least partially encapsulating the first group and the second group.

Aspect 2: The package of aspect 1, wherein the first group is located laterally to the second group, and wherein the third encapsulation layer is located laterally between the first group and the second group.

Aspect 3: The package of aspects 1 through 2, wherein the third encapsulation layer is a separate encapsulation layer from the first encapsulation layer and/or the second encapsulation layer.

Aspect 4: The package of aspects 1 through 2, wherein the first encapsulation layer, the second encapsulation layer and the third encapsulation layer form a continuous and/or contiguous encapsulation layer.

Aspect 5: The package of aspects 1 through 4, wherein the first group further comprises a fourth metallization portion coupled to the first encapsulation layer, wherein the first encapsulation layer is located between the first metallization portion and the fourth metallization portion, wherein the second group further comprises a fifth metallization portion coupled to the second encapsulation layer, and wherein the second encapsulation layer is located between the second metallization portion and the fifth metallization portion.

Aspect 6: The package of aspect 5, wherein the fourth metallization portion and the fifth metallization portion are coupled to the third metallization portion.

Aspect 7: The package of aspect 5, further comprises a first plurality of via interconnects located in the first encapsulation layer, wherein the first plurality of via interconnects are coupled to the first metallization portion and the fourth metallization portion, and a second plurality of via interconnects located in the second encapsulation layer, wherein the second plurality of via interconnects are coupled to the second metallization portion and the fifth metallization portion.

Aspect 8: The package of aspect 5, wherein the third encapsulation layer is located laterally between the fourth metallization portion and the fifth metallization portion.

Aspect 9: The package of aspect 5, wherein the third encapsulation layer is coupled to and touching (i) a surface of the third metallization portion, (ii) a side surface of the fourth metallization portion and (iii) a side surface of the fifth metallization portion.

Aspect 10: The package of aspect 5, wherein the lateral size of the third metallization portion is greater than the combined lateral size of the fourth metallization portion and the fifth metallization portion.

Aspect 11: The package of aspects 1 through 10, wherein the first group is a first sub-package, and wherein the second group is a second sub-package.

Aspect 12: The package of aspects 1 through 11, wherein the third metallization portion is coupled to the first encapsulation layer and the second encapsulation layer.

Aspect 13: The package of aspects 1 through 12, further comprises a first plurality of via interconnects located in the first encapsulation layer, wherein the first plurality of via interconnects are coupled to the first metallization portion and the third metallization portion, and a second plurality of via interconnects located in the second encapsulation layer, wherein the second plurality of via interconnects are coupled to the second metallization portion and the third metallization portion.

Aspect 14: The package of aspects 1 through 13, further comprises a fourth encapsulation layer that at least partially encapsulates the first integrated device and the second integrated device, and a fifth encapsulation layer that at least partially encapsulates the third integrated device and the fourth integrated device.

Aspect 15: The package of aspect 14, wherein the fourth encapsulation layer is part of the first group, and wherein the fifth encapsulation layer is part of the second group.

Aspect 16: The package of aspect 15, wherein the first encapsulation layer, the second encapsulation layer, the third encapsulation layer, the fourth encapsulation layer and/or the fourth encapsulation layer include a same material.

Aspect 17: The package of aspect 15, wherein the first encapsulation layer, the second encapsulation layer, the third encapsulation layer, the fourth encapsulation layer and/or the fourth encapsulation layer include a different material composition.

Aspect 18: The package of aspect 15, wherein the first encapsulation layer, the second encapsulation layer, the third encapsulation layer, the fourth encapsulation layer and/or the fourth encapsulation layer includes at least one boundary interface between two or more encapsulation layers.

Aspect 19: The package of aspect 15, wherein the first encapsulation layer, the second encapsulation layer, the third encapsulation layer, the fourth encapsulation layer and/or the fourth encapsulation layer are free of a boundary interface between two or more encapsulation layers.

Aspect 20: The package of aspects 1 through 19, wherein the first integrated device is coupled to the first metallization portion through a first plurality of pillar interconnects and/or a first plurality of solder interconnects, wherein the second integrated device is coupled to the first metallization portion through a second plurality of pillar interconnects and/or a second plurality of solder interconnects, wherein the third integrated device is coupled to the second metallization portion through a third plurality of pillar interconnects and/or a third plurality of solder interconnects, and wherein the fourth integrated device is coupled to the second metallization portion through a fourth plurality of pillar interconnects and/or a fourth plurality of solder interconnects.

Aspect 21: A method for fabricating a package. The method provides a first group comprising a first metallization portion; a first integrated device coupled to the first metallization portion; a second integrated device coupled to the first metallization portion; a first encapsulation layer coupled to the first metallization portion; a first passive device located in the first encapsulation layer; and a first bridge located in the first encapsulation layer. The method provides a second group comprising a second metallization portion; a second integrated device coupled to the second metallization portion; a second integrated device coupled to the second metallization portion; a second encapsulation layer coupled to the second metallization portion; a second passive device located in the second encapsulation layer; and a second bridge located in the second encapsulation layer. The method forms and couples a third metallization portion to the first group and the second group. The method forms a third encapsulation layer that at least partially encapsulates the first group and the second group.

Aspect 22: The method of aspect 21, wherein the first group further comprises a fourth metallization portion coupled to the first encapsulation layer, wherein the first encapsulation layer is located between the first metallization and the fourth metallization portion, wherein the second group further comprises a fifth metallization portion coupled to the second encapsulation layer, and wherein the second encapsulation layer is located between the second metallization and the fifth metallization portion.

Aspect 23: The method of aspect 22, wherein the fourth metallization portion and the fifth metallization portion are coupled to the third metallization portion.

Aspect 24: The method of aspects 21 through 23, wherein the first group is a first sub-package, and wherein the second group is a second sub-package.

Aspect 25: A device comprising aspects 1 through 20, wherein the device is from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first group comprising:
a first metallization portion;
a first integrated device coupled to the first metallization portion;
a second integrated device coupled to the first metallization portion;
a first encapsulation layer coupled to the first metallization portion;
a first passive device located in the first encapsulation layer; and
a first bridge located in the first encapsulation layer;
a second group comprising:
a second metallization portion;
a third integrated device coupled to the second metallization portion;
a fourth integrated device coupled to the second metallization portion;
a second encapsulation layer coupled to the second metallization portion;
a second passive device located in the second encapsulation layer; and
a second bridge located in the second encapsulation layer;
a third metallization portion coupled to the first group and the second group; and
a third encapsulation layer at least partially encapsulating the first group and the second group.

2. The package of claim 1,
wherein the first group is located laterally to the second group, and
wherein the third encapsulation layer is located laterally between the first group and the second group.

3. The package of claim 1, wherein the third encapsulation layer is a separate encapsulation layer from the first encapsulation layer and/or the second encapsulation layer.

4. The package of claim 1, wherein the first encapsulation layer, the second encapsulation layer and the third encapsulation layer form a continuous and/or contiguous encapsulation layer.

5. The package of claim 1,
wherein the first group further comprises a fourth metallization portion coupled to the first encapsulation layer,
wherein the first encapsulation layer is located between the first metallization portion and the fourth metallization portion,
wherein the second group further comprises a fifth metallization portion coupled to the second encapsulation layer, and
wherein the second encapsulation layer is located between the second metallization portion and the fifth metallization portion.

6. The package of claim 5, wherein the fourth metallization portion and the fifth metallization portion are coupled to the third metallization portion.

7. The package of claim 5, further comprising:
a first plurality of via interconnects located in the first encapsulation layer, wherein the first plurality of via interconnects are coupled to the first metallization portion and the fourth metallization portion, and
a second plurality of via interconnects located in the second encapsulation layer, wherein the second plurality of via interconnects are coupled to the second metallization portion and the fifth metallization portion.

8. The package of claim 5, wherein the third encapsulation layer is located laterally between the fourth metallization portion and the fifth metallization portion.

9. The package of claim 5, wherein the third encapsulation layer is coupled to and touching (i) a surface of the third metallization portion, (ii) a side surface of the fourth metallization portion and (iii) a side surface of the fifth metallization portion.

10. The package of claim 5, wherein the lateral size of the third metallization portion is greater than the combined lateral size of the fourth metallization portion and the fifth metallization portion.

11. The package of claim 1,
wherein the first group is a first sub-package, and
wherein the second group is a second sub-package.

12. The package of claim 1, wherein the third metallization portion is coupled to the first encapsulation layer and the second encapsulation layer.

13. The package of claim 1, further comprising:
a first plurality of via interconnects located in the first encapsulation layer, wherein the first plurality of via interconnects are coupled to the first metallization portion and the third metallization portion, and
a second plurality of via interconnects located in the second encapsulation layer, wherein the second plurality of via interconnects are coupled to the second metallization portion and the third metallization portion.

14. The package of claim 1, further comprising:
a fourth encapsulation layer that at least partially encapsulates the first integrated device and the second integrated device, and
a fifth encapsulation layer that at least partially encapsulates the third integrated device and the fourth integrated device.

15. The package of claim 14,
wherein the fourth encapsulation layer is part of the first group, and
wherein the fifth encapsulation layer is part of the second group.

16. The package of claim 15, wherein the first encapsulation layer, the second encapsulation layer, the third encapsulation layer, the fourth encapsulation layer and/or the fourth encapsulation layer include a same material.

17. The package of claim 15, wherein the first encapsulation layer, the second encapsulation layer, the third encapsulation layer, the fourth encapsulation layer and/or the fourth encapsulation layer include a different material composition.

18. The package of claim 15, wherein the first encapsulation layer, the second encapsulation layer, the third encapsulation layer, the fourth encapsulation layer and/or the fourth encapsulation layer includes at least one boundary interface between two or more encapsulation layers.

19. The package of claim 15, wherein the first encapsulation layer, the second encapsulation layer, the third encapsulation layer, the fourth encapsulation layer and/or the fourth encapsulation layer are free of a boundary interface between two or more encapsulation layers.

20. The package of claim 1,
wherein the first integrated device is coupled to the first metallization portion through a first plurality of pillar interconnects and/or a first plurality of solder interconnects,
wherein the second integrated device is coupled to the first metallization portion through a second plurality of pillar interconnects and/or a second plurality of solder interconnects,
wherein the third integrated device is coupled to the second metallization portion through a third plurality of pillar interconnects and/or a third plurality of solder interconnects, and
wherein the fourth integrated device is coupled to the second metallization portion through a fourth plurality of pillar interconnects and/or a fourth plurality of solder interconnects.
